(19) United States
(12) Patent Application Publication
(10) Pub. No.: US 2025/0333553 A1
(43) Pub. Date: Oct. 30, 2025

(54) POLYMER, RESIST COMPOSITION INCLUDING THE SAME, AND PATTERN FORMATION METHOD USING THE RESIST COMPOSITION

(71) Applicant: Samsung Electronics Co., Ltd., Suwon-si (KR)

(72) Inventors: Chanjae AHN, Suwon-si (KR); Minsang KIM, Suwon-si (KR); Beomseok KIM, Suwon-si (KR); Hana KIM, Suwon-si (KR); Sungan DO, Suwon-si (KR); Yonghoon MOON, Suwon-si (KR); Hoyoon PARK, Suwon-si (KR); Aram JEON, Suwon-si (KR); Jungha CHAE, Suwon-si (KR); Sungwon CHOI, Suwon-si (KR)

(73) Assignee: Samsung Electronics Co., Ltd., Suwon-si (KR)

(21) Appl. No.: 18/883,234

(22) Filed: Sep. 12, 2024

(30) Foreign Application Priority Data
Apr. 26, 2024 (KR) 10-2024-0056300

(51) Int. Cl. C08F 12/24; C08F 8/00; G03F 7/004; G03F 7/039

(52) U.S. Cl. CPC C08F 12/24; G03F 7/0045; G03F 7/0395; C08F 8/00

(57) ABSTRACT

Provided are a polymer, a resist composition including the same, and a pattern formation method using the resist composition. The polymer includes a polymer chain including a first repeating unit represented by Formula 1 below, and a terminus including at least one of an amino group, a hydroxy group, a C₁-C₁₀ alkoxy group, or a C₁-C₁₀ ester group:

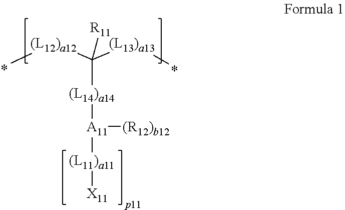

wherein, in Formula 1, L₁₁ to L₁₄, a11 to a14, A₁₁, X₁₁, R₁₁, R₁₂, b12, and p11 are as defined in the specification.

### CROSS-REFERENCE TO RELATED APPLICATION

This application is based on and claims priority under 35 U.S.C. § 119 to Korean Patent Application No. 10-2024-0056300, filed on Apr. 26, 2024, in the Korean Intellectual Property Office, the disclosure of which is incorporated by reference herein in its entirety.

### BACKGROUND

### 1. Field

The inventive concepts relate to polymers, resist compositions including the same, and pattern formation methods using the resist compositions.

### 2. Description of the Related Art

In semiconductor manufacturing, resists have physical properties that change in response to light, and resists are used to form fine patterns. From among these resists, chemically amplified resists have been widely used. A chemically amplified resist enables patterning by changing the solubility of a base resin in a developer by reaction of an acid, which is formed by a reaction between light and a photoacid generator, with the base resin again.

In particular, when high-energy rays with relatively very high energy such as EUV are used, there is a problem in that the number of photons may be significantly small even when irradiating light of the same energy.

### SUMMARY

Some example embodiments of the inventive concepts provide a polymer capable of providing improved sensitivity and/or resolution, a resist composition including the same, and a pattern formation method using the resist composition. Such a polymer having improved sensitivity and/or resolution may be configured to enable a resist composition that can act effectively even when a small amount is used and that can provide improved sensitivity and/or improved resolution.

Additional aspects will be set forth in part in the description which follows and, in part, will be apparent from the description, or may be learned by practice of the presented embodiments of the inventive concepts.

According to some example embodiments of the inventive concepts, a polymer includes a polymer chain including a first repeating unit represented by Formula 1, and a terminus including at least one of an amino group, a hydroxy group, a C₁-C₁₀ alkoxy group, or a C₁-C₁₀ ester group:

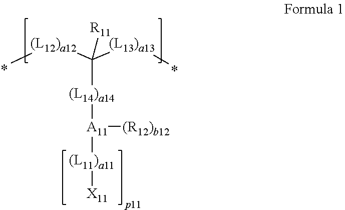

wherein, in Formula 1, L₁₁ to L₁₄ are each independently a single bond, O, S, C(═O), C(═O)O, OC(═O), C(═O)NH, NHC(═O), S(═O), S(═O)₂, S(═O)₂O, OS(═O)₂, or a linear, branched, or cyclic C₁-C₃₀ divalent hydrocarbon group optionally containing a heteroatom, a11 to a14 are each independently an integer from 1 to 4, A₁₁ is a C₆-C₃₀ aryl group or a C₁-C₃₀ heteroaryl group, R₁₁ is halogen, a cyano group, or a linear, branched, or cyclic C₁-C₃₀ monovalent hydrocarbon group optionally containing a heteroatom, R₁₂ is hydrogen, deuterium, a halogen, a cyano group, a hydroxy group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom, X₁₁ is a hydroxy group, a carboxylate group, an ester moiety, a sulfonate moiety, a carbonate moiety, a lactone moiety, a sultone moiety, a carboxylic anhydride moiety, a linear, branched, or cyclic C₁-C₃₀ monovalent hydrocarbon group optionally containing a heteroatom, or an acid labile group, b12 is an integer from 1 to 10, p11 is an integer from 1 to 3, and * is a binding site with an adjacent atom.

According to some example embodiments, a resist composition includes the above-described polymer, a photoacid generator, and an organic solvent.

L₁₁ to L₁₄ may each independently be a single bond, O, S, C(═O), C(═O)O, OC(═O), C(═O)NH, NHC(═O), S(═O), S(═O)₂:S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

A₁₁ may be one of a phenyl group, a biphenyl group, a terphenyl group, a naphthyl group, a phenanthrenyl group, an anthracenyl group, a triphenylenyl group, a pyrenyl group, a chrysenyl group, a pyrrolyl group, a thiophenyl group, a furanyl group, an imidazolyl group, a pyrazolyl group, a thiazolyl group, an oxazolyl group, a pyridinyl group, a pyrazinyl group, a pyrimidinyl group, a pyridazinyl group, an indolyl group, a quinolinyl group, an isoquinolinyl group, a benzoquinolinyl group, a quinoxalinyl group, a quinazolinyl group, or a cynolinyl group.

A₁₁ may be one of a phenyl group, a biphenyl group, a terphenyl group, or a naphthyl group.

R₁₁ may be one of a halogen; a cyano group; a C₁-C₂₀ alkyl group; a C₃-C₂₀ cycloalkyl group; or a C₆-C₂₀ aryl group. Each of the C₁-C₂₀ alkyl group, the C₃-C₂₀ cycloalkyl group, and the C₆-C₂₀ aryl group may be unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

R₁₂ may be one of hydrogen; deuterium; a halogen; a cyano group; a hydroxy group; an amino group; a carboxylate group; a thiol group; a C₁-C₂₀ alkyl group; a C₃-C₂₀ cycloalkyl group; or a C₆-C₂₀ aryl group. Each of the C₁-C₂₀ alkyl group, the C₃-C₂₀ cycloalkyl group, and the C₆-C₂₀ aryl group may be unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

X₁₁ may be one of an acid labile group; a hydroxy group; a carboxylate group; an ester moiety; a sulfonate moiety; a carbonate moiety; a lactone moiety; a sultone moiety; a carboxylic anhydride moiety; a C₁-C₂₀ alkoxy group; a C₃-C₂₀ cycloalkoxy group; or a C₆-C₂₀ aryloxy group. Each of the C₁-C₂₀ alkoxy group, the C₃-C₂₀ cycloalkoxy group, and the C₆-C₂₀ aryloxy group may be unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

The acid labile group may be represented by any one of Formulas 6-1 to 6-11:

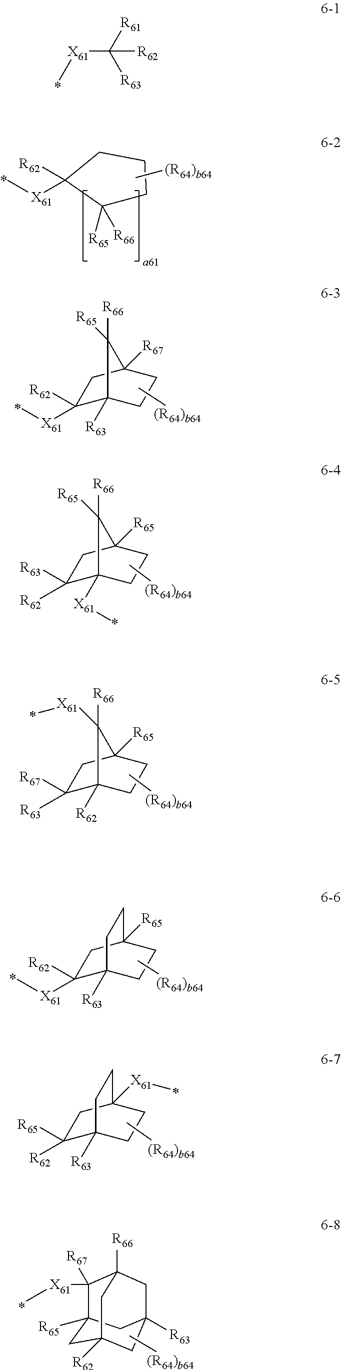

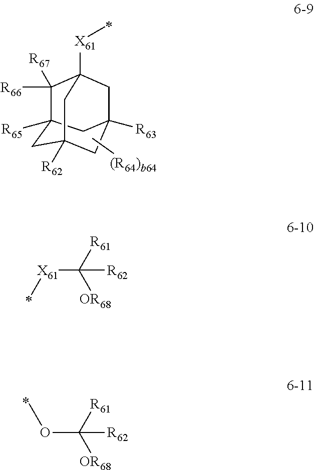

wherein, in Formulas 6-1 to 6-11, X₆₁ is an ester moiety, a sulfonate moiety, a carbonate moiety, or a carbamate moiety, a61 is an integer from 0 to 6, R₆₁ and R₆₈ are each independently a linear, branched, or cyclic C₁-C₂₀ monovalent hydrocarbon group optionally containing a heteroatom, R₆₂ to R₆₇ are each independently hydrogen, deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom, two adjacent groups of R₆₁ to R₆₈ are optionally bonded to each other to form a ring, b64 is an integer from 1 to 10, and * is a binding site with an adjacent atom of Formula 1.

The terminus may be represented by any one of Formulas 10-1 to 10-4:

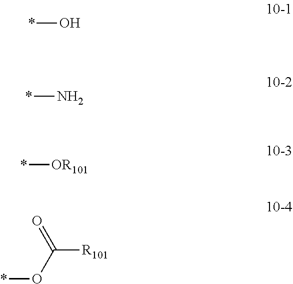

wherein, in Formulas 10-1 to 10-4, R₁₀₁ is a methyl group, an ethyl group, an n-propyl group, an iso-propyl group, an n-butyl group, an iso-butyl group, a sec-butyl group, a tert-butyl group, an n-pentyl group, an iso-pentyl group, a 2-methylbutyl group, a sec-pentyl group, a tert-pentyl group, a neo-pentyl group, a 3-pentyl group, or a 3-methyl-2-butyl group, and * is a binding site with the polymer chain.

The terminus may be *—OH.

The first repeating unit may be represented by Formula 1-1:

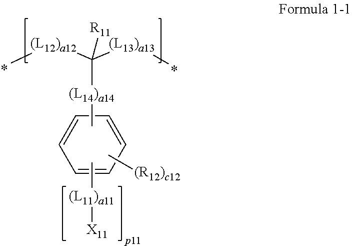

wherein, in Formula 1-1, L₁₁ to L₁₄, a11 to a14, X₁₁, R₁₁, R₁₂, and p11 are the same as L₁₁ to L₁₄, a11 to a14, X₁₁, R₁₁, R₁₂, and p11, respectively, as defined in Formula 1, c12 is an integer from 1 to 4, and * is a binding site with an adjacent atom.

The first repeating unit may be selected from Group I:

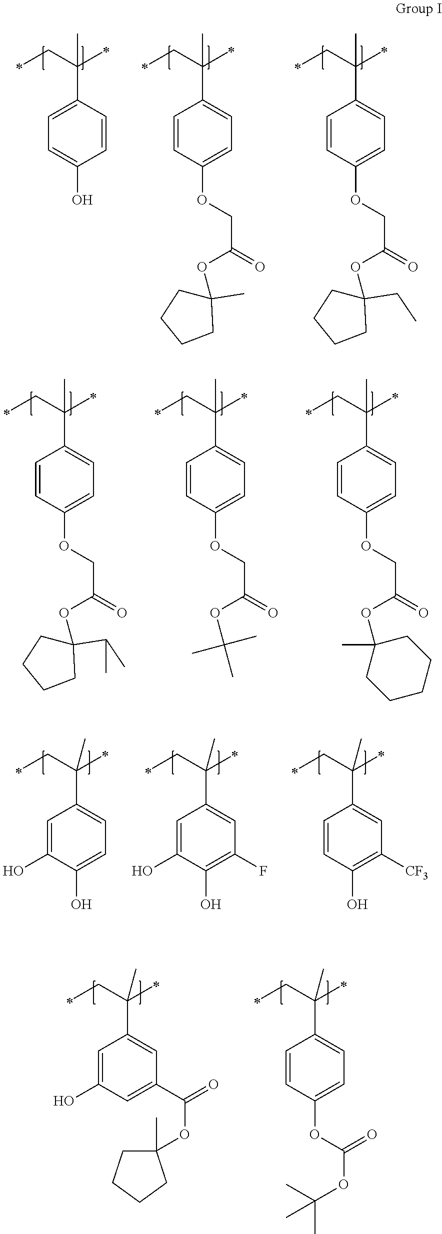

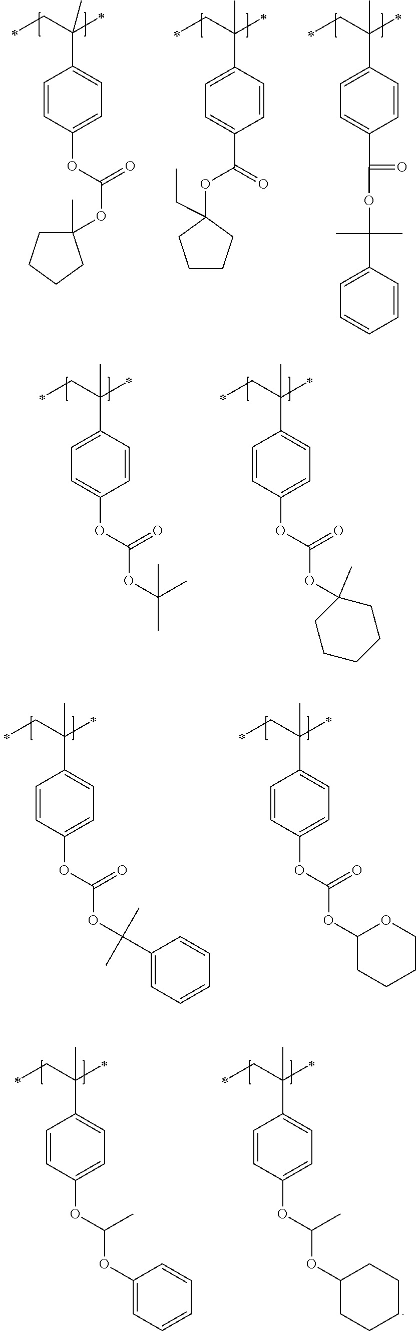

The polymer chain may further include at least one of a second repeating unit represented by Formula 2 or a third repeating unit represented by Formula 3:

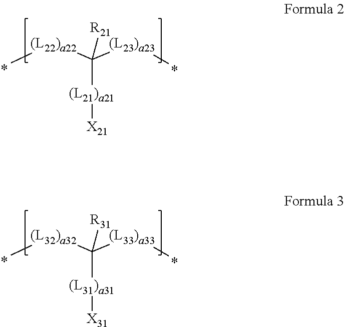

wherein, in Formula 2 and Formula 3, L₂₁ to L₂₃ and L₃₁ to L₃₃ are each independently a single bond, O, S, C(═O), C(═O)O, OC(═O), C(═O)NH, NHC(═O), S(═O), S(═O)₂, S(═O)₂O, OS(═O)₂, or a linear, branched, or cyclic C₁-C₃₀ divalent hydrocarbon group optionally containing a heteroatom, a21 to a23 and a31 to a33 are each independently an integer from 1 to 4, R₂₁ and R₃₁ are each independently hydrogen, a deuterium, a halogen, a cyano group, a hydroxy group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom, X₂₁ is a non-acid labile group, X₃₁ is an acid labile group, and * is a binding site with an adjacent atom.

According to some example embodiments, a resist composition may include the above-described polymer, a photoacid generator, and an organic solvent.

The photoacid generator may be represented by Formula 7:

B₇₁_{⁺}A₇₁_{^{−}} Formula 7

wherein, in Formula 7, B₇₁_{⁺} is represented by Formula 7A, A₇₁_{^{−}} is represented by any one of Formulas 7B to 7D, and B₇₁_{⁺} and A₇₁_{^{−}} are optionally linked to each other through a carbon-carbon covalent bond:

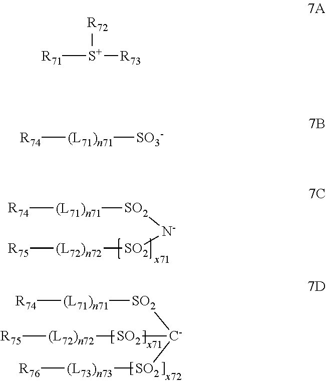

wherein, in Formulas 7A to 7D, L₇₁ to L₇₃ are each independently a single bond or CRR′, R and R′ are each independently hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group, n71 to n73 are each independently 1, 2, or 3, x71 and x72 are each independently 0 or 1, R₇₁ to R₇₃ are each independently a linear, branched, or cyclic C₁-C₃₀ monovalent hydrocarbon group optionally containing a heteroatom, adjacent two of R₇₁ to R₇₃ are optionally bonded to each other to form a condensed ring, and R₇₄ to R₇₆ are each independently hydrogen, a halogen, or a linear, branched, or cyclic C₁-C₃₀ monovalent hydrocarbon group optionally containing a heteroatom.

The resist composition may further include a quencher.

The quencher may be represented by Formula 8:

B₈₁_{⁺}A₈₁_{^{−}} Formula 8

wherein, in Formula 8, B₈₁_{⁺} is represented by any one of Formulas 8A to 8C, A₈₁_{^{−}} is represented by any one of Formulas 8D to 8F, and B₈₁_{⁺} and A₈₁_{^{−}} are optionally linked to each other through a carbon-carbon covalent bond,

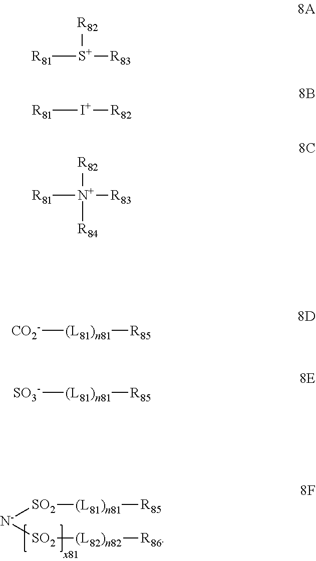

wherein, in Formulas 8A to 8F, L₈₁ and L₈₂ are each independently a single bond or CRR′, R and R′ are each independently hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group, n81 and n82 are each independently 1, 2, or 3, x81 is 0 or 1, R₈₁ to R₈₄ are each independently a linear, branched, or cyclic C₁-C₃₀ monovalent hydrocarbon group optionally containing a heteroatom, adjacent two of R₈₁ to R₈₄ are optionally bonded to each other to form a condensed ring, and R₈₅ and R₈₆ are each hydrogen, a halogen, or a linear, branched, or cyclic C₁-C₃₀ monovalent hydrocarbon group optionally containing a heteroatom.

According to some example embodiments of the inventive concepts, a pattern formation method includes applying the above-described resist composition to form a resist film, exposing at least a portion of the resist film to high-energy rays, and developing the exposed resist film based on using a developer.

The exposing may be performed based on irradiating at least the portion of the photoresist film with at least one of ultraviolet rays, deep ultraviolet (DUV) rays, extreme ultraviolet (EUV) rays, X-rays, γ-rays, electron beams (Ebs), or α-rays.

The exposed resist film may include an exposed portion and an unexposed portion, and the developing may include removing the exposed portion.

### BRIEF DESCRIPTION OF THE DRAWINGS

The above and other aspects, features, and advantages of certain embodiments will be more apparent from the following description taken in conjunction with the accompanying drawings, in which:

FIG. 1 is a flowchart illustrating a method according to some example embodiments;

FIGS. 2A, 2B, and 2C are side cross-sectional views illustrating a pattern formation method according to some example embodiments;

FIGS. 3A, 3B, 3C, 3D, and 3E are cross-sectional side views illustrating a method of forming a patterning structure, according to some example embodiments; and

FIGS. 4A, 4B, 4C, 4D, and 4E are side cross-sectional views illustrating a method of forming a semiconductor device, according to some example embodiments.

### DETAILED DESCRIPTION

Reference will now be made in detail to some example embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the FIGS., to explain aspects. As used herein, the term “and/or” includes any and all combinations of one or more of the associated listed items. Expressions such as “at least one of,” when preceding a list of elements, modify the entire list of elements and do not modify the individual elements of the list.

Since the present inventive concepts can apply various transformations and have various example embodiments, specific example embodiments will be illustrated in the drawings and described in detail in the detailed description. However, it should be understood that this is not intended to limit the inventive concepts to specific example embodiments, and includes all transformations, equivalents, and substitutes included in the spirit and scope of the inventive concepts. In describing the inventive concepts, when it is determined that the specific description of the known related art unnecessarily obscures the gist of the inventive concepts, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cr-Cy” means that the number (e.g., quantity) of carbon atoms constituting a substituent is in a range of x to y, wherein x and y may each be any natural number. For example, “C₁-C₆” means that the number of carbon atoms constituting a substituent is in a range of 1 to 6, and “C₆-C₂₀” means that the number of carbon atoms constituting a substituent is in a range of 6 to 20.

As used herein, the term “monovalent hydrocarbon group” may refer to a monovalent residue derived from an organic compound including carbon and hydrogen or a derivative thereof, and specific examples thereof may include: linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); monovalent saturated cycloaliphatic hydrocarbon groups (cycloalkyl groups) (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (alkenyl group or alkynyl group) (for example, an allyl group); a monovalent unsaturated cycloaliphatic hydrocarbon group (cycloalkenyl group) (for example, 3-cyclohexenyl); aryl groups (for example, a phenyl group, a 1-naphthyl group, and a 2-naphthyl group); arylalkyl groups (for example, a benzyl group and a diphenylmethyl group); heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group); and any combination thereof. In addition, in these groups, some hydrogen atoms may be substituted by a moiety including one or more heteroatoms such as oxygen, sulfur, nitrogen, or halogen, or some carbon atoms may be substituted by a moiety including one or more heteroatoms such as oxygen, sulfur, or nitrogen so that the groups may include a hydroxy group, a cyano group, a carboxyl group, an ether bond, an ester bond, a sulfonate ester bond, a carbonyl moiety, an ester moiety, a sulfonate moiety, a carbonate moiety, a lactone moiety, a sultone moiety, a carboxylic anhydride moiety, or a haloalkyl moiety.

As used herein, the term “divalent hydrocarbon group” is a divalent residue and means that any one hydrogen atom of the monovalent hydrocarbon group is replaced with a binding site with an adjacent atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

As used herein, the term “alkyl group” refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and the like. As used herein, the term “alkylene group” refers to a linear or branched saturated aliphatic hydrocarbon divalent group, and specific examples thereof include a methylene group, an ethylene group, a propylene group, a butylene group, an isobutylene group, and the like.

As used herein, the term “halogenated alkyl group” refers to a group in which one or more hydrogen atoms of an alkyl group are substituted with halogen, and specific examples thereof include CF₃ and the like.

As used herein, the term “alkoxy group” refers to a monovalent group having a formula of —OA₁₀₁, wherein A₁₀₁ is an alkyl group. Specific examples thereof include a methoxy group, an ethoxy group, an isopropyloxy group, and the like.

As used herein, the term “alkylthio group” refers to a monovalent group having a formula of —SA₁₀₁, wherein A₁₀₁ is an alkyl group.

As used herein, the term “halogenated alkoxy group” refers to a group in which one or more hydrogen atoms of an alkoxy group are substituted with halogen, and specific examples thereof include —OCF₃ and the like.

As used herein, the term “halogenated alkylthio group” refers to a group in which one or more hydrogen atoms of an alkylthio group are substituted with halogen, and specific examples thereof include —SCF3 and the like.

As used herein, the term “cycloalkyl group” refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. As used herein, the term “cycloalkylene group” refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

As used herein, the term “cycloalkoxy group” refers to a monovalent group having a formula of —OA₁₀₂, wherein A₁₀₂ is a cycloalkyl group. Specific examples thereof include a cyclopropoxy group, a cyclobutoxy group, and the like.

As used herein, the term “cycloalkylthio group” refers to a monovalent group having a formula of —SA₁₀₂, wherein A₁₀₂ is a cycloalkyl group.

As used herein, the term “heterocycloalkyl group” may be a group in which some carbon atoms of the cycloalkyl group are replaced by a moiety including one or more heteroatoms, for example, oxygen, sulfur, or nitrogen, and specifically, the heterocycloalkyl group may include an ether bond, an ester bond, a sulfonate ester bond, a sulfonate bond, carbonate, a lactone ring, a sultone ring, or a carboxylic anhydride moiety. As used herein, the term “heterocycloalkylene group” is a group in which some carbon atoms of the cycloalkylene group are replaced by a moiety including one or more heteroatoms, for example, oxygen, sulfur, or nitrogen.

As used herein, the term “heterocycloalkoxy group” refers to a monovalent group having a formula of —OA₁₀₃, wherein A₁₀₃ is a heterocycloalkyl group.

As used herein, the term “alkenyl group” refers to a linear or branched unsaturated aliphatic hydrocarbon monovalent group including one or more carbon-carbon double bonds. As used herein, the term “alkenylene group” refers to a linear or branched unsaturated aliphatic hydrocarbon divalent group including one or more carbon-carbon double bonds.

As used herein, the term “alkenyloxy group” refers to a monovalent group having a formula of —OA₁₀₄, wherein A₁₀₄ is an alkenyl group.

As used herein, the term “cycloalkenyl group” refers to a monovalent unsaturated hydrocarbon cyclic group including one or more carbon-carbon double bonds. As used herein, the term “cycloalkenylene group” refers to a divalent unsaturated hydrocarbon cyclic group including one or more carbon-carbon double bonds.

As used herein, the term “cycloalkenyloxy group” refers to a monovalent group having a formula of-OA₁₀₅, wherein A₁₀₅ is a cycloalkenyl group.

As used herein, the term “heterocycloalkenyl group” is a group in which some carbon atoms of the cycloalkenylene group are replaced by a moiety including one or more heteroatoms, for example, oxygen, sulfur, or nitrogen. As used herein, the term “heterocycloalkenylene group” is a group in which some carbon atoms of the cycloalkenylene group are replaced by a moiety including one or more heteroatoms, for example, oxygen, sulfur, or nitrogen.

As used herein, the term “heterocycloalkenyloxy group” refers to a monovalent group having a formula of-OA₁₀₆, wherein A₁₀₆ is a heterocycloalkenyl group.

As used herein, the term “alkynyl group” refers to a linear or branched unsaturated aliphatic hydrocarbon monovalent group including one or more carbon-carbon triple bonds.

As used herein, the term “alkynyloxy group” refers to a monovalent group having a formula of-OA₁₀₇, wherein A₁₀₇ is an alkynyl group.

As used herein, the term “aryl group” refers to a monovalent group having a carbocyclic aromatic system, and specific examples thereof include a phenyl group, a naphthyl group, an anthracenyl group, a phenanthrenyl group, a pyrenyl group, a chrysenyl group, and the like.

As used herein, the term “aryloxy group” refers to a monovalent group having a formula of-OA₁₀₈, wherein A₁₀₈ is an aryl group.

As used herein, the term “heteroaryl group” refers to a monovalent group having a heterocyclic aromatic system, and specific examples thereof include a pyridinyl group, a pyrimidinyl group, a pyrazinyl group, and the like. As used herein, the term “heteroarylene group” refers to a divalent group having a heterocyclic aromatic system.

As used herein, the term “heteroaryloxy group” refers to a monovalent group having a formula of-OA₁₀₉, wherein A₁₀₉ is a heteroaryl group.

As used herein, the term “substituent” includes: deuterium, a halogen, a hydroxy group, a cyano group, a nitro group, a carboxylate group, an amino group, an ether moiety, a carbonyl moiety, an ester moiety, a sulfonate moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen, a hydroxy group, a cyano group, a nitro group, a carboxylate group, an amino group, an ether moiety, a carbonyl moiety, an ester moiety, a sulfonate moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and any combination thereof; and any combination thereof.

In order to clearly explain the present inventive concepts in the drawings, parts that are not related to the description are omitted, and similar parts are given similar reference numerals throughout the specification. In the flowchart described with reference to the drawings, the order of operations may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component.

In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same.

While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Hereinafter, some example embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, example embodiments set forth herein are merely examples and various changes may be made therein.

### [Polymer]

A polymer according to some example embodiments may include a polymer chain including a first repeating unit represented by Formula 1, and a terminus including at least one of an amino group, a hydroxy group, a C₁-C₁₀ alkoxy group, or a C₁-C₁₀ ester group:

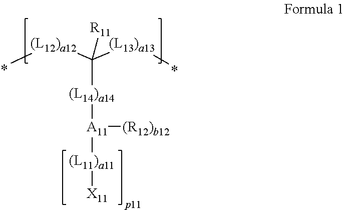

In Formula 1, L₁₁ to L₁₄ may each independently be a single bond, O, S, C(═O), C(═O)O, OC(═O), C(═O)NH, NHC(═O), S(═O), S(═O)₂, S(═O)₂O, OS(═O)₂, or a linear, branched, or cyclic C₁-C₃₀ divalent hydrocarbon group optionally containing a heteroatom, a11 to a14 may each independently be an integer from 1 to 4, A₁₁ may be a C₆-C₃₀ aryl group or a C₁-C₃₀ heteroaryl group, R₁₁ may be halogen, a cyano group, or a linear, branched, or cyclic C₁-C₃₀ monovalent hydrocarbon group optionally containing a heteroatom, R₁₂ may be hydrogen, deuterium, a halogen, a cyano group, a hydroxy group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom, X₁₁ may be a hydroxy group, a carboxylate group, an ester moiety, a sulfonate moiety, a carbonate moiety, a lactone moiety, a sultone moiety, a carboxylic anhydride moiety, a linear, branched, or cyclic C₁-C₃₀ monovalent hydrocarbon group optionally containing a heteroatom, or an acid labile group, b12 may be an integer from 1 to 10, p11 may be an integer from 1 to 3, and * may be a binding site with an adjacent atom.

For example, in Formula 1, 11 to L₁₄ may each independently be a single bond, 0, S, C(═O), C(═O)O, OC(═O), C(═O)NH, NHC(═O), S(═O), S(═O)₂, S(═O)₂0, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

As another example, in Formula 1, 11 to L₁₄ may each independently be one of a single bond; 0; C(═O); C(═O)O; OC(═O); C(═O)NH; NHC(═O); a C₁-C₂₀ alkylene group; a C₃-C₂₀ cycloalkylene group; a C₃-C₂₀ heterocycloalkylene group; a C₂-C₂₀ alkenylene group; a C₃-C₂₀ cycloalkenylene group; a C₃-C₂₀ heterocycloalkenylene group; a C₆-C₂₀ arylene group; or a C₁-C₂₀ heteroarylene group. Each of the C₁-C₂₀ alkylene group, the C₃-C₂₀ cycloalkylene group, the C₃-C₂₀ heterocycloalkylene group, the C₂-C₂₀ alkenylene group, the C₃-C₂₀ cycloalkenylene group, the C₃-C₂₀ heterocycloalkenylene group, the C₆-C₂₀ arylene group, and the C₁-C₂₀ heteroarylene group may independently be unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As another example, in Formula 1, 11 to L₁₄ may each independently be one of a single bond; 0; C(═O); C(═O)O; OC(═O); C(═O)NH; NHC(═O); a C₁-C₂₀ alkylene group; a C₃-C₂₀ cycloalkylene group; a C₃-C₂₀ heterocycloalkylene group; a phenylene group; or a naphthylene group. Each of the C₁-C₂₀ alkylene group, the C₃-C₂₀ cycloalkylene group, the C₃-C₂₀ heterocycloalkylene group, the phenylene group, and the naphthylene group may independently be unsubstituted or substituted with deuterium, a halogen, a C₁-C₂₀ alkyl group, a C₁-C₂₀ halogenated alkyl group, a C₁-C₂₀ alkoxy group, a phenyl group, a naphthyl group, or any combination thereof.

Specifically, in Formula 1, L₁₁ and L₁₄ may each independently be one of O or a C₁-C₅ alkylene group.

In Formula 1, a11 to a14 may each refer to the number (e.g., quantity) of repetitions of L₁₁ to L₁₄.

For example, in Formula 1, a11 to a14 may each independently be an integer from 1 to 3.

As another example, in Formula 1, a11 to a14 may each independently be 1.

For example, in Formula 1, A₁₁ may be one of a phenyl group, a biphenyl group, a terphenyl group, a naphthyl group, a phenanthrenyl group, an anthracenyl group, a triphenylenyl group, a pyrenyl group, a chrysenyl group, a pyrrolyl group, a thiophenyl group, a furanyl group, an imidazolyl group, a pyrazolyl group, a thiazolyl group, an oxazolyl group, a pyridinyl group, a pyrazinyl group, a pyrimidinyl group, a pyridazinyl group, an indolyl group, a quinolinyl group, an isoquinolinyl group, a benzoquinolinyl group, a quinoxalinyl group, a quinazolinyl group, or a cynolinyl group.

Specifically, in Formula 1, A₁₁ may be one of a phenyl group, a biphenyl group, a terphenyl group, or a naphthyl group.

More specifically, in Formula 1, A₁₁ may be a phenyl group.

For example, in Formula 1, R₁₁ may be one of a halogen; a cyano group; a C₁-C₂₀ alkyl group; a C₃-C₂₀ cycloalkyl group; or a C₆-C₂₀ aryl group. Each of the C₁-C₂₀ alkyl group, the C₃-C₂₀ cycloalkyl group, and the C₆-C₂₀ aryl group may independently be unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As another example, in Formula 1, R₁₁ may be one of a halogen; a cyano group; or a C₁-C₂₀ alkyl group unsubstituted or substituted with deuterium, a halogen, a cyano group, or any combination thereof.

Specifically, in Formula 1, R₁₁ may be CH₃, CH₂CH₃, F, CH₂F, CHF₂, CF₃, CHFCH₃, CHFCH₂F, CHFCHF₂, CHFCF₃, CF₂CH₃, CF₂CH₂F, CF₂CHF₂, CF₂CF₃, C₁, CH₂Cl, CHCl₂, CCl₃, CHClCH₃, CHClCH₂Cl, CHClCHCl₂, CHClCCl₃, CCl₂CH₃, CCl₂CH₂Cl, CCl₂CHCl₂, or CCl₂CCl₃.

For example, in Formula 1, R₁₂ may be one of hydrogen; deuterium; a halogen; a cyano group; a hydroxy group; an amino group; a carboxylate group; a thiol group; a C₁-C₂₀ alkyl group; a C₃-C₂₀ cycloalkyl group; or a C₆-C₂₀ aryl group. Each of the C₁-C₂₀ alkyl group, the C₃-C₂₀ cycloalkyl group, and the C₆-C₂₀ aryl group may independently be unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As another example, in Formula 1, R₁₂ may be hydrogen, deuterium, a halogen, a cyano group, a hydroxy group, an amino group, a carboxylate group, a thiol group, a C₁-C₂₀ alkyl group, a C₁-C₂₀ halogenated alkyl group, a C₃-C₂₀ cycloalkyl group, or a C₆-C₂₀ aryl group.

For example, in Formula 1, X₁₁ may be one of an acid labile group; a hydroxy group; a carboxylate group; an ester moiety; a sulfonate moiety; a carbonate moiety; a lactone moiety; a sultone moiety; a carboxylic anhydride moiety; a C₁-C₂₀ alkoxy group; a C₃-C₂₀ cycloalkoxy group; or a C₆-C₂₀ aryloxy group. Each of the C₁-C₂₀ alkoxy group, the C₃-C₂₀ cycloalkoxy group, and the C₆-C₂₀ aryloxy group may independently be unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As another example, in Formula 1, X₁₁ may be one of an acid labile group; a hydroxy group; a C₁-C₂₀ alkoxy group; a C₃-C₂₀ cycloalkoxy group; or a C₆-C₂₀ aryloxy group. Each of the C₁-C₂₀ alkoxy group, the C₃-C₂₀ cycloalkoxy group, and the C₆-C₂₀ aryloxy group may independently be unsubstituted or substituted with deuterium, a halogen, a cyano group, a hydroxy group, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As used herein, an acid labile group may include a group containing tertiary non-cyclic alkyl carbon, a group containing tertiary alicyclic carbon, or acetal.

Specifically, the acid labile group may be represented by any one of Formulas 6-1 to 6-11 below:

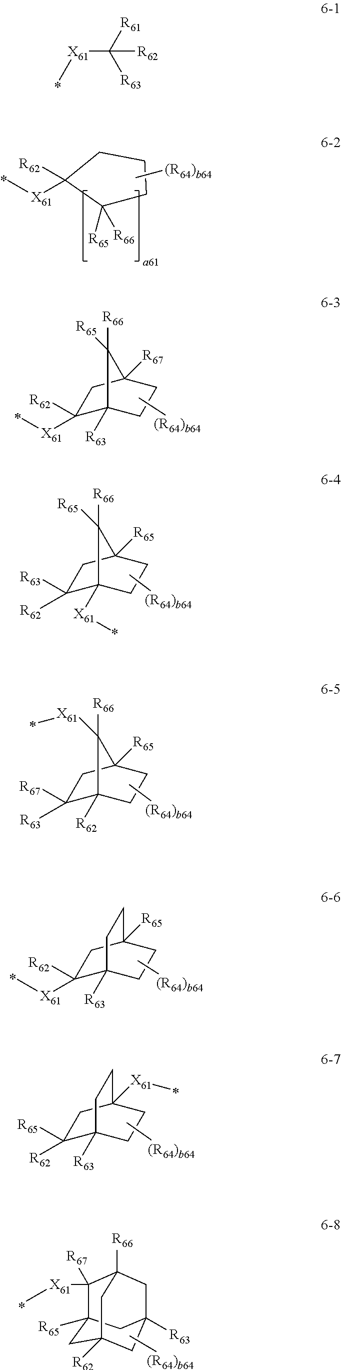

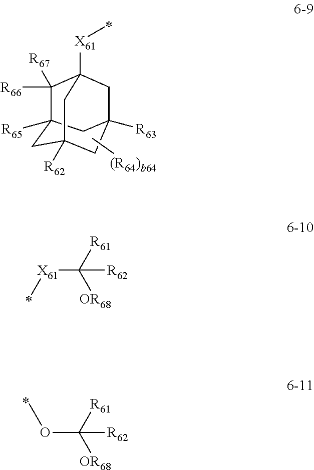

In Formulas 6-1 to 6-11, X₆₁ may be an ester moiety, a sulfonate moiety, a carbonate moiety, or a carbamate moiety, a61 may be an integer from 0 to 6, R₆₁ and R₆₈ may each independently be a linear, branched, or cyclic C₁-C₂₀ monovalent hydrocarbon group optionally containing a heteroatom, R₆₂ to R₆₇ may each independently be hydrogen, deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom, two adjacent groups of R₆₁ to R₆₈ may be optionally bonded to each other to form a ring, b64 may be an integer from 1 to 10, and * may be a binding site with an adjacent atom of Formula 1.

Specifically, the acid labile group may be represented by any one of Formulas 6-21 to 6-29 below:

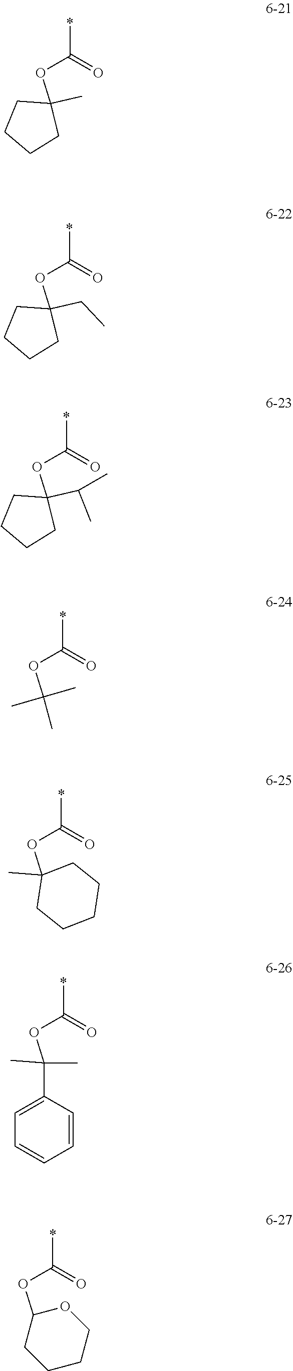

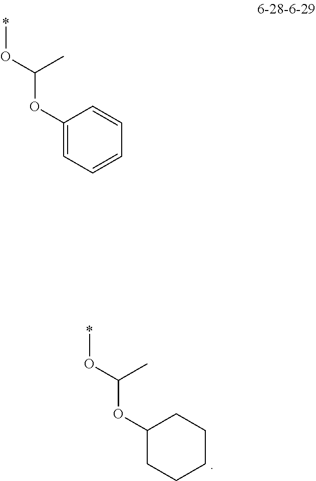 [SMILES: *OC(C)Oc1ccccc1 ; *OC(C)OC1CCCCC1]

In Formulas 6-21 to 6-29, * may be a binding site with an adjacent atom of Formula 1.

Specifically, in Formula 1, X₁₁ may be represented by a hydroxy group and any one of Formulas 6-21 to 6-29.

For example, the terminus may be represented by any one of Formulas 10-1 to 10-4 below:

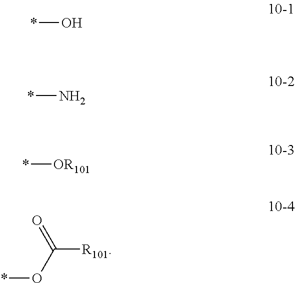

In Formulas 10-1 to 10-4, R₁₀₁ may be a methyl group, an ethyl group, an n-propyl group, an iso-propyl group, an n-butyl group, an iso-butyl group, a sec-butyl group, a tert-butyl group, an n-pentyl group, an iso-pentyl group, a 2-methylbutyl group, a sec-pentyl group, a tert-pentyl group, a neo-pentyl group, a 3-pentyl group, or a 3-methyl-2-butyl group, and * may be a binding site with the polymer chain.

Specifically, the terminus may be *—OH.

For example, in Formula 1, p11 may be 1 or 2.

In some example embodiments, the first repeating unit may be represented by Formula 1-1:

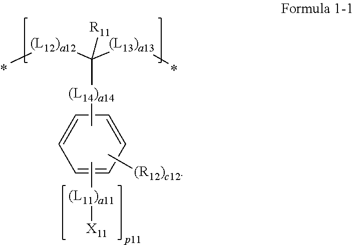

In Formula 1-1, L₁₁ to L₁₄, a11 to a14, X₁₁, R₁₁, R₁₂, and p11 may be the same L₁₁ to L₁₄, a11 to a14, X₁₁, R₁₁, R₁₂, and p11, respectively, as defined as above in Formula 1, c12 may be an integer from 1 to 4, and * may be a binding site with an adjacent atom.

Specifically, the first repeating unit may be selected from Group I below:

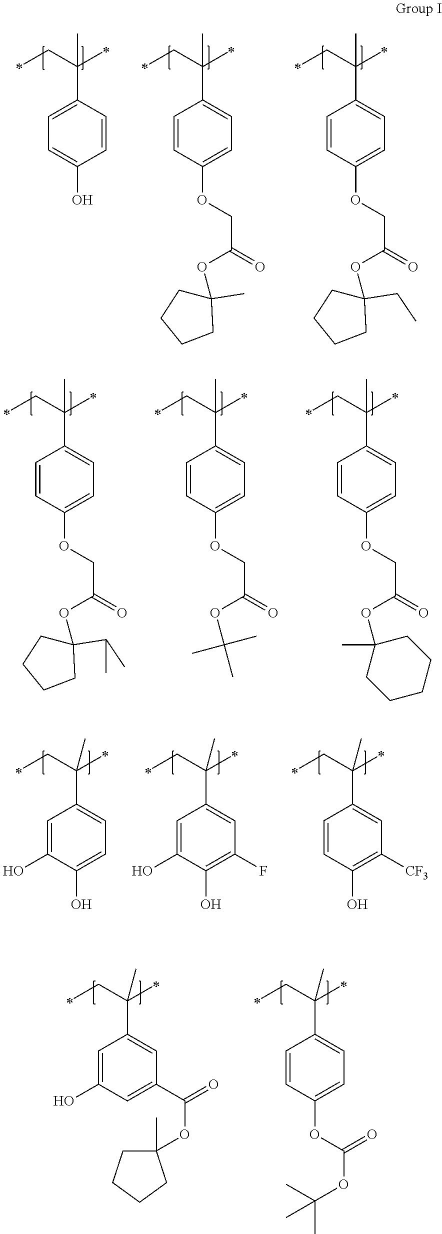

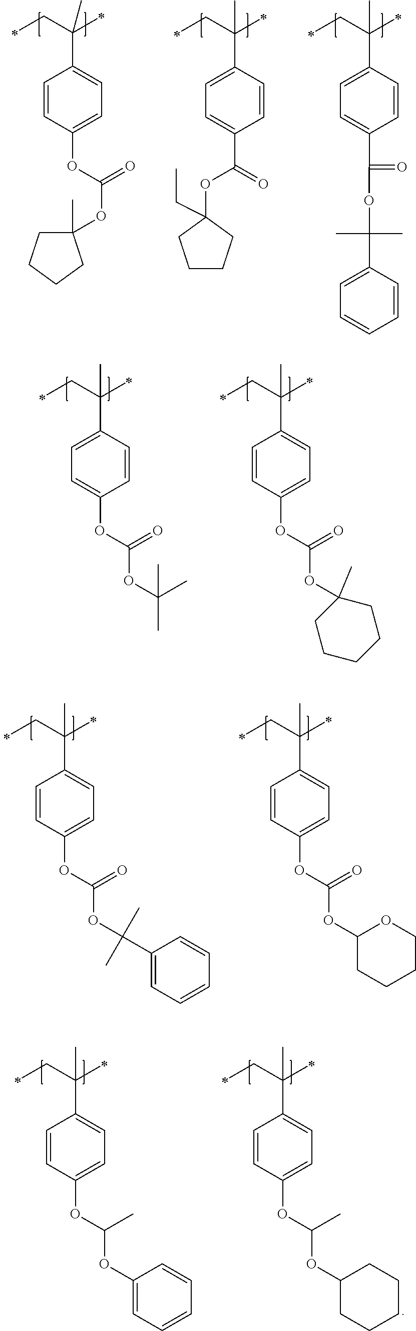

In some example embodiments, the polymer chain may further include at least one of a second repeating unit represented by Formula 2 below or a third repeating unit represented by Formula 3 below:

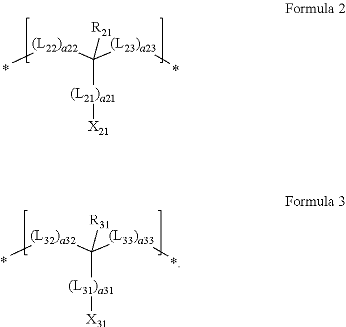

In Formula 2 and Formula 3, L₂₁ to L₂₃ and L₃₁ to L₃₃ may each independently be a single bond, O, S, C(═O), C(═O)O, OC(═O), C(═O)NH, NHC(═O), S(═O), S(═O)₂, S(═O)₂O, OS(═O)₂, or a linear, branched, or cyclic C₁-C₃₀ divalent hydrocarbon group optionally containing a heteroatom, a21 to a23 and a31 to a33 may each independently be an integer from 1 to 4, R₂₁ and R₃₁ may each independently be hydrogen, a deuterium, a halogen, a cyano group, a hydroxy group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom, X₂₁ may be a non-acid labile group, X₃₁ may be an acid labile group, and * may be a binding site with an adjacent atom (e.g., an adjacent atom of the polymer chain).

Specifically, in Formula 2 and Formula 3, R₂₁ and R₃₁ may each independently be selected from a halogen; a cyano group, and a C₁-C₂₀ alkyl group, a C₃-C₂₀ cycloalkyl group, and a C₆-C₂₀ aryl group, each unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

More specifically, in Formula 2 and Formula 3, R₂₁ and R₃₁ may each independently be a halogen; a cyano group; or a C₁-C₂₀ alkyl group unsubstituted or substituted with deuterium, a halogen, a cyano group, or any combination thereof.

For example, in Formula 2, X₂₁ may be hydrogen, a halogen, a cyano group, a hydroxy group, a carboxylate group, a thiol group, an amino group; or a linear, branched, or cyclic C₁-C₃₀ monovalent hydrocarbon group optionally containing at least one polar moiety of a halogen, a cyano group, a hydroxy group, a carboxylate group, a thiol group, O, C═O, C(═O)O, OC(═O), S═O, S(═O)O, OS(═O), a lactone moiety, a sultone moiety, or a carboxylic anhydride moiety.

As another example, in Formula 2, X₂₁ may be selected from hydrogen, a hydroxy group, and groups represented by Formulas 5-1 to 5-10 below:

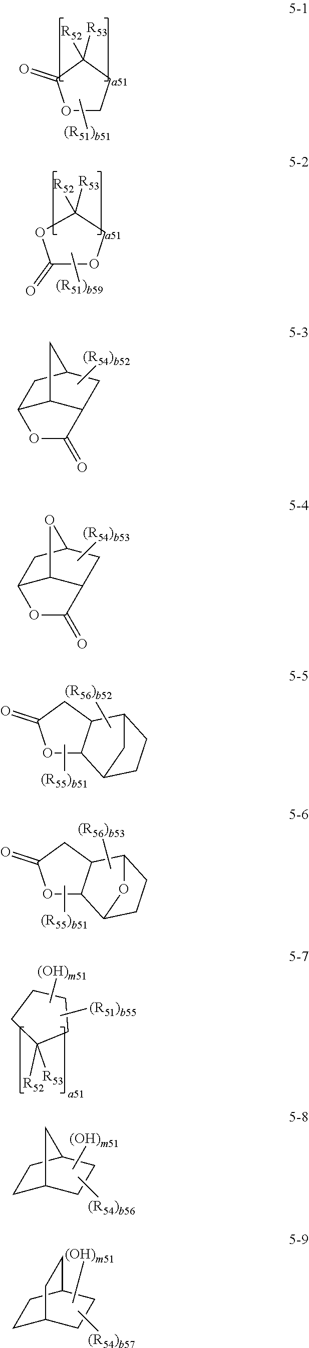

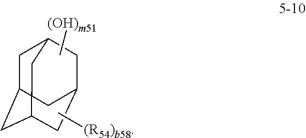

In Formulas 5-1 to 5-10, a51 may be 1 or 2, R₅₁ to R₅₆ may each independently be a binding site with an adjacent atom, hydrogen, deuterium, a halogen, a cyano group, a hydroxy group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom, One of R₅₁ to R₅₃, one of R₅₄, and one of R₅₅ or R₅₆ may each be a binding site with an adjacent atom, b51 may be an integer from 1 to 4, b52 may be an integer from 1 to 10, b53 may be an integer from 1 to 8, b55 may be an integer from 1 to 7, b56 may be an integer from 1 to 11, b57 may be an integer from 1 to 13, b58 may be an integer from 1 to 15, b59 may be an integer from 1 to 2, and m51 may be an integer from 1 to 4.

For example, in Formula 3, X₃₁ may include a group containing tertiary non-cyclic alkyl carbon, a group containing tertiary alicyclic carbon, or acetal.

As another example, in Formula 3, X₃₁ may be represented by any one of Formulas 6-1 to 6-11.

In some example embodiments, the polymer may consist of or comprise the first repeating unit.

The polymer may have a weight average molecular weight Mw of about 1,000 to about 500,000, specifically, about 2,000 to about 100,000, or more specifically, about 3,000 to about 10,000 which is measured through gel permeation chromatography using a tetrahydrofuran (THF) solvent and polystyrene as standard materials. When such a range is satisfied, while a fine pattern is formed at a desired level, the deterioration of a pattern profile may be minimized. Accordingly, the resist composition may be more suitable for forming a fine pattern.

A polydispersity index (PDI: Mw/Mn) of the polymer may be in a range of about 1.0 to about 3.0. When such a range is satisfied, the dispersibility and/or compatibility of the polymer may be easy to control, and a possibility of foreign materials remaining on a pattern may be reduced, or the deterioration of a pattern profile may be minimized. Accordingly, the resist composition may be more suitable for forming a fine pattern.

The physical properties of the polymer itself may be changed due to high-energy rays. Specifically, while a main chain of the polymer decomposes, a molecular weight of the polymer may decrease, and thus the solubility thereof in a developer may increase.

In addition, since R₁₁ is not hydrogen in the polymer, the stability of radicals/cations generated by decomposition of the main chain may be improved, and thus a decomposition rate and/or a decomposition speed of the main chain may be improved compared as polymers in which R₁₁ is hydrogen. As a result, a resist composition may have improved sensitivity to even a small amount of photons from high energy rays such as EUV and thus may have improved sensitivity and/or resolution and thus may be able to enable improved resolution and reliable formation of fine patterns in manufactured semiconductors, based on the resist composition including a polymer having a first repeating unit represented by Formula 1 wherein R₁₁ is not hydrogen (e.g., R₁₁ is a halogen, a cyano group, or a linear, branched, or cyclic C₁-C₃₀ monovalent hydrocarbon group optionally containing a heteroatom).

In addition, since the terminus of the polymer is a substituent that becomes a good leaving group by an acid such as OH, a decomposition rate and/or a decomposition speed of the main chain may be improved by an acid generated from a photoacid generator. As a result, a resist composition may have improved sensitivity to even a small amount of photons from high energy rays such as EUV and thus may have improved sensitivity and/or resolution and thus may be able to enable improved resolution and reliable formation of fine patterns in manufactured semiconductors, based on the resist composition including a polymer having terminus that becomes a good leaving group by an acid such as OH.

In addition, since the polymer optionally has an acid labile group in a side chain, while the side chain is decomposed by an acid generated from a photoacid generator, the solubility of the polymer in a developer, in particular, the solubility of the polymer in a basic developer that does not use an organic solvent, may increase. Therefore, as compared with other positive resist compositions in which an organic solvent has to be used as a developer, environmental pollution may be reduced based on performing a pattern formation method, as part of forming a semiconductor device, using a resist composition that includes the polymer, based on the polymer optionally having an acid labile group in a side chain.

In addition, since the polymer has R11, which is not hydrogen, and optionally has an acid labile group in the side chain, a rapid decomposition reaction of the main chain of polymer by high-energy rays and an additional deprotection and decomposition reaction of the side chain by an acid generated from a photoacid generator may occur simultaneously. Ultimately, since the polymer in a high molecular weight state has a lower molecular weight and a content (or concentration) of a polar functional group dissolvable in a basic developer is increased as compared with initial exposure, the solubility of the polymer in the developer may be further increased, thereby efficiently forming a fine pattern having improved resolution even when an exposure amount is lowered, thereby enabling the formation of semiconductor devices having fine patterns with reduced high energy ray photon amounts, reduced environmental pollution, and with improved reliability of the fine pattern formation such that the reliability of the formed semiconductor devices having fine patterns may be improved (due to reduced likelihood of process defects in the fine patterns formed using the resist composition that includes the polymer).

The polymer may have relatively high resistance to oxygen and/or moisture and may have a relatively high a glass transition temperature Tg (for example, a glass transition temperature Tg of 80° C. or more), and the physical properties thereof may be changed only by high-energy rays, thereby providing a resist composition with improved storage stability, process stability, and the like.

Unlike chemically amplified photoresists which may cause a problem that, as a formed acid diffuses to an unexposed area, pattern uniformity is lowered or surface roughness is increased, since the solubility of the polymer is not changed by an acid, the low uniformity of a pattern and/or the occurrence of defects due to acid diffusion may be reduced.

The polymer may be prepared through any suitable method, for example, by dissolving unsaturated bond-containing monomer(s) in an organic solvent and then performing cationic polymerization on the unsaturated bond-containing monomer(s) in a cationic initiator.

The structure (composition) of the polymer may be identified by performing Fourier transform infrared (FT-IR) analysis, nuclear magnetic resonance (NMR) analysis, fluorescence X-ray (XRF) analysis, mass spectrometry, ultraviolet (UV) analysis, single crystal X-ray structure analysis, powder X-ray diffraction (PXRD) analysis, liquid chromatography (LC) analysis, size exclusion chromatography (SEC) analysis, thermal analysis, or the like. A detailed identification method is as described in Examples.

### [Resist Composition]

According to some example embodiments, provided is a resist composition including the above-described polymer, a photoacid generator, and an organic solvent. The resist composition may have properties such as improved developability and/or improved resolution.

The solubility of the resist composition in a developer may be changed by exposure to high-energy rays. The resist composition may be a positive resist composition in which an exposed portion of a resist film is dissolved and removed to form a positive resist pattern, or a negative resist composition in which an unexposed portion of a resist film is dissolved and removed to form a negative resist pattern. Specifically, the resist composition may be a positive resist composition.

In addition, the resist composition according to some example embodiments may be used for an alkaline developing process in which an alkaline developer is used for a developing process when a resist pattern is formed and may also be used for a solvent developing process in which an organic solvent-containing developer (hereinafter referred to as an organic developer) is used for developing treatment. In particular, the resist composition according to some example embodiments may be used for an alkaline developing process.

Since the physical properties of the polymer are changed by exposure (e.g., exposure to incident light, including for example EUV incident light), the resist composition may not substantially include a compound having a molecular weight of 1,000 or more, other than the polymer.

The polymer may be used (e.g., included in the resist composition) in a range of about 0.1 parts by weight to about 80 parts by weight with respect to 100 parts by weight of the resist composition. Specifically, the polymer may be used in a range of about 0.5 parts by weight to about 5 parts by weight with respect to 100 parts by weight of the resist composition. When such a range is satisfied, any performance loss (e.g., a performance loss with regard to a resist composition including the polymer used for pattern formation in semiconductor device manufacturing), for example, reduction in sensitivity and/or the formation of foreign particles due to lack of solubility, may be reduced, minimized, or prevented. As a result, a resist composition including the polymer may be configured to enable improved reliability (e.g., reduced likelihood of process defects) of fine patterns formed using a pattern formation process (e.g., based on using the resist composition to form a photoresist film that is exposed to high-energy rays and developed).

Since the polymer is as described above, an organic solvent and any components contained as necessary will be described below. In addition, one type of a polymer may be used in the resist composition, or two or more different types of polymers may be used in combination.

### <Photoacid Generator>

The photoacid generator may be any compound capable of generating an acid when exposed to high-energy rays such as UV rays, deep UV (DUV) rays, electron beams (Ebs), extreme ultraviolet (EUV) rays, X-rays, α-rays, or γ-rays.

The photoacid generator may include at least one of a sulfonium salt, an iodonium salt, or any combination thereof.

In some example embodiments, the photoacid generator may be represented by Formula 7:

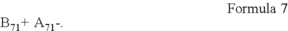

In Formula 7, B₇₁_{⁺} may be represented by Formula 7A below, A₇₁_{^{−}} may be represented by any one of Formulas 7B to 7D below, and B₇₁_{⁺} and A₇₁_{^{−}} may be optionally linked to each other through a carbon-carbon covalent bond:

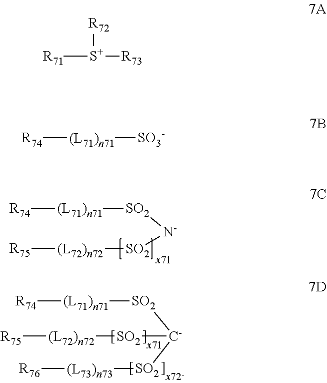

In Formulas 7A to 7D, L₇₁ to L₇₃ may each independently be a single bond or CRR′, R and R′ may each independently be hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group, n71 to n73 may each independently be 1, 2, or 3, x71 and x72 may each independently be 0 or 1, R₇₁ to R₇₃ may each independently be a linear, branched, or cyclic C₁-C₃₀ monovalent hydrocarbon group optionally containing a heteroatom, adjacent two of R₇₁ to R₇₃ may be optionally bonded to each other to form a condensed ring, and R₇₄ to R₇₆ may each independently be hydrogen, a halogen, or a linear, branched, or cyclic C₁-C₃₀ monovalent hydrocarbon group optionally containing a heteroatom.

For example, in Formula 7, B₇₁_{⁺} may be represented by Formula 7A, and A₇₁_{^{−}} may be represented by Formula 7B. Specifically, in Formula 7A, R₇₁ to R₇₃ may each be a phenyl group.

The photoacid generator may be included in a range of about 0.01 parts by weight to about 40 parts by weight, about 0.1 parts by weight to about 40 parts by weight, or about 0.1 parts by weight to about 20 parts by weight with respect to about 100 parts by weight of the polymer. When such a range is satisfied, appropriate resolution may be achieved, and problems related to foreign material particles after developing or during stripping may be reduced. As a result, a resist composition including the photoacid generator may be configured to enable improved reliability (e.g., reduced likelihood of process defects) of fine patterns formed using a pattern formation process (e.g., based on using the resist composition to form a photoresist film that is exposed to high-energy rays and developed).

As the photoacid generator, one type of a photoacid generator may be used, or two or more different types of photoacid generators may be mixed and used.

### <Organic Solvent>

The organic solvent included in the resist composition is not particularly limited as long as the organic solvent may dissolve or disperse the polymer and any components contained as needed. As the organic solvent, one type of an organic solvent may be used, or two or more different types of organic solvents may be used in combination. In addition, a mixed solvent in which water and an organic solvent are mixed may be used.

Examples of the organic solvent may include, for example, an alcohol-based solvent, an ether-based solvent, a ketone-based solvent, an amide-based solvent, an ester-based solvent, a sulfoxide-based solvent, a hydrocarbon-based solvent, and the like.

More specifically, examples of the alcohol-based solvent may include a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol; a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol; and a polyhydric alcohol-containing ether-based solvent such as ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether (PGME), propylene glycol dimethyl ether, propylene glycol monoethyl ether, propylene glycol monopropyl ether, propylene glycol monobutyl ether, dipropylene glycol monomethyl ether, dipropylene glycol monoethyl ether, or dipropylene glycol monopropyl ether.

Examples of the ether-based solvent may include: a dialkyl ether-based solvent such as diethyl ether, dipropyl ether, or dibutyl ether; a cyclic ether-based solvent such as THE or tetrahydropyran; and an aromatic ring-containing ether-based solvent such as diphenyl ether or anisole.

Examples of the ketone-based solvent may include: a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone; a cyclic ketone-based solvent such as cyclopentanone, cyclohexanone, cycloheptanone, cyclooctanone, or methylcyclohexanone; 2,4-pentanedione, acetonyl acetone, and acetophenone.

Examples of the amide-based solvent may include: a cyclic amide-based solvent such as N,N′-dimethylimidazolidinone or N-methyl-2-pyrrolidone; and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent may include: an acetate ester-based solvent such as methyl acetate, ethyl acetate (EA), n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate; a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, or dipropylene glycol monoethyl ether acetate; a lactone-based solvent such as γ-butyrolactone or δ-valerolactone; a carbonate-based solvent such as dimethyl carbonate, diethyl carbonate, ethylene carbonate, or propylene carbonate; a lactate ester-based solvent such as methyl lactate, ethyl lactate (EL), n-butyl lactate, or n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, or diethyl phthalate.

Examples of the sulfoxide-based solvent may include dimethyl sulfoxide, diethyl sulfoxide, and the like.

Examples of the hydrocarbon-based solvent may include: an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

Specifically, the organic solvent may be one of an alcohol-based solvent, an amide-based solvent, an ester-based solvent, a sulfoxide-based solvent, or any combination thereof. More specifically, the organic solvent may be selected from PGME, propylene glycol monoethyl ether, PGMEA, N-methyl-2-pyrrolidone, N,N-dimethylacetamide, EL, dimethyl sulfoxide, or any combination thereof.

The organic solvent may be used (e.g., included in the resist composition) in a range of about 200 parts by weight to about 5,000 parts by weight, specifically, about 400 parts by weight to about 3,000 parts by weight, with respect to 100 parts by weight of the polymer.

### <any Components>

If necessary, the resist composition may further include a quencher, a surfactant, a crosslinking agent, a leveling agent, a colorant, or any combination thereof.

The resist composition may further include the quencher to improve developability or the like.

The quencher may be a salt that generates an acid with lower acidity than an acid generated from an acid generator.

The quencher may include at least one selected from an ammonium salt, a sulfonium salt, an iodonium salt, and any combination thereof.

In some example embodiments, the quencher may be represented by Formula 8 below:

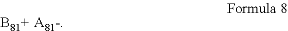

In Formula 8, B₈₁_{⁺} may be represented by any one of Formulas 8A to 8C below, A₈₁_{^{−}} may be represented by any one of Formulas 8D to 8F below, and B₈₁_{⁺} and A₈₁_{^{−}} may be optionally linked to each other through a carbon-carbon covalent bond,

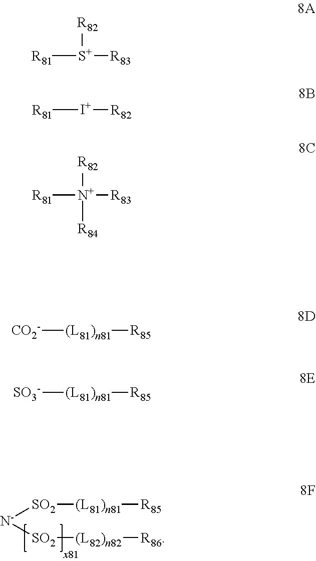

In Formulas 8A to 8F, L₈₁ and L₈₂ may each independently be a single bond or CRR′, R and R′ may each independently be hydrogen, deuterium, a halogen, a cyano group, a hydroxy group, a C₁-C₃₀ alkyl group, a C₁-C₂₀ halogenated alkyl group, a C₁-C₃₀ alkoxy group, a C₃-C₃₀ cycloalkyl group, or a C₃-C₃₀ cycloalkoxy group, n81 and n82 may each independently be 1, 2, or 3, x81 may be 0 or 1, R₈₁ to R₈₄ may each independently be a linear, branched, or cyclic C₁-C₃₀ monovalent hydrocarbon group, adjacent two of R₈₁ to R₈₄ may be optionally bonded to each other to form a ring, and R₈₅ and R₈₆ may each be hydrogen, a halogen, or a linear, branched, or cyclic C₁-C₃₀ monovalent hydrocarbon group optionally containing a heteroatom.

The quencher may be included in a range of about 0.01 parts by weight to about 30 parts by weight, about 0.05 parts by weight to about 20 parts by weight, or about 0.1 parts by weight to about 10 parts by weight with respect to 100 parts by weight of the polymer. When such a range is satisfied, appropriate resolution may be achieved, and problems related to foreign material particles after developing or during stripping may be reduced. As a result, a resist composition including the quencher may be configured to enable improved reliability (e.g., reduced likelihood of process defects) of fine patterns formed using a pattern formation process (e.g., based on using the resist composition to form a photoresist film that is exposed to high-energy rays and developed).

As the quencher, one type of a quencher may be used, or two or more different types of quenchers may be mixed and used.

The resist composition may further include the surfactant to improve coatability, developability, and the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 75 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC-103, Surflon™ SC-104, Surflon™ SC-105, and Surflon™ SC-106 (manufactured by AGC Seimi Chemical Co., Ltd.).

The surfactant may be included (e.g., in the resist composition) in a range of about 0 parts by weight to about 20 parts by weight with respect to about 100 parts by weight of the polymer. As the surfactant, one type of a surfactant may be used, or two or more different types of surfactants may be mixed and used.

A method of preparing the resist composition is not particularly limited, and for example, a method of mixing a polymer and any components added as needed in an organic solvent may be used. A temperature or time during mixing is not particularly limited. If necessary, filtration may be performed after mixing.

### [Pattern Formation Method]

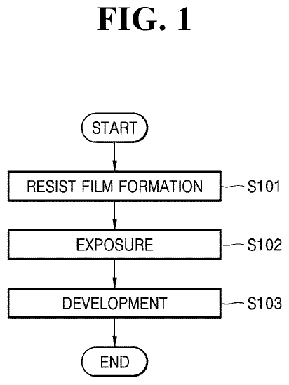

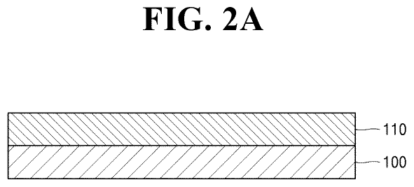

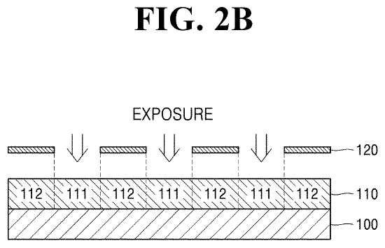

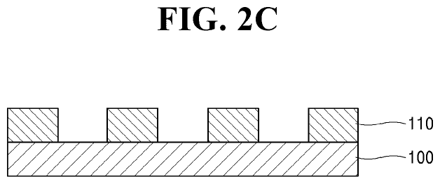

Hereinafter, a pattern formation method according to some example embodiments will be described in more detail with reference to FIGS. 1 and 2A to 2C. FIG. 1 is a flowchart illustrating the pattern formation method according to some example embodiments, and FIGS. 2A to 2C are side cross-sectional views illustrating the pattern formation method according to some example embodiments. Hereinafter, an example of the pattern formation method using a positive resist composition will be described in detail, but one or more embodiments are not limited thereto.

Referring to FIG. 1, a method may include a pattern formation method that may include operation S101 of applying a resist composition to form a resist film, operation S102 of exposing at least a portion of the resist film to high-energy rays, and operation S103 of developing the exposed resist film by using a developer. In some example embodiments, the method may further include manufacturing a semiconductor device, an electronic device, or any combination thereof based on the developed exposed resist film. Such operations may be omitted if necessary or may be performed in a different order.

First, a substrate 100 may be prepared. The substrate 100 may include, for example, a semiconductor substrate such as a silicon substrate or a germanium substrate, glass, quartz, ceramic, or copper. In some example embodiments, the substrate 100 may include a Group Ill-V compound such as GaP, GaAs, or GaSb.

As shown at FIGS. 1 and 2A, a resist composition may be applied to a desired thickness on the substrate 100, specifically, through a coating method, to form a resist film 110. If necessary, heating (referred to as pre-bake (PB) or post-annealing bake (PAB)) may be performed to remove an organic solvent remaining on the resist film 110. The resist film 110 may include a resist composition according to any of the example embodiments and may include the polymer according to any of the example embodiments.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. Specifically, the resist film 110 may have a thickness of about 10 nm to about 300 nm. More specifically, the resist film 110 may have a thickness of about 30 nm to about 200 nm.

A lower limit of a temperature of the PB may be 60° C. or more, specifically, 80° C. or more. In addition, an upper limit of the temperature of the PB may be about 150° C. or less, specifically, about 140° C. or less. A lower limit of a time of the PB may be 5 seconds or more, specifically, 10 seconds or more. An upper limit of the time of the PB may be 600 seconds or less, specifically, 300 seconds or less.

Before the applying of the resist composition onto the substrate 100, an etching target film (not shown) may be further formed on the substrate 100. The etching target film may refer to a layer on which an image is transferred from a resist pattern and converted into a certain pattern. In some example embodiments, the etching target film may be formed to include, for example, an insulating material such as silicon oxide, silicon nitride, or silicon oxynitride. In some example embodiments, the etching target film may be formed to include a conductive material such as metal, metal nitride, metal silicide, or metal silicide nitride. In some example embodiments, the etching target film may be formed to include a semiconductor material such as polysilicon.

In some example embodiments, an antireflection film may be further formed on the substrate 100 to increase or maximize the efficiency of a resist. The antireflection film may be an organic or inorganic antireflection film.

In some example embodiments, a protective film may be further provided on the resist film 110 to reduce the influence of alkaline impurities or the like included during a process. When immersion exposure is performed, for example, a protective film for immersion may also be provided on the resist film 110 to avoid direct contact between an immersion medium and the resist film 110.

Next, as shown at FIGS. 1 and 2B, at least a portion of the resist film 110 may be exposed to high-energy rays. For example, high-energy rays passing through a mask 120 may be irradiated onto at least a portion of the resist film 110. Thus, the resist film 110 may have an exposed portion 111 and an unexposed portion 112.

In some example embodiments, the exposure may be performed by irradiating high-energy rays through a mask with a certain pattern by using a liquid such as water as a medium. Examples of the high-energy rays may include electromagnetic waves such as UV rays, DUV rays, EUV rays (with a wavelength of 13.5 nm), X-rays, and γ-rays; and charged particle beams such as Ebs and a rays. Irradiating the high-energy rays may be collectively referred to as “exposure.”

Examples of an exposure light source may include various light sources such as a light source that emits laser light in a UV region, such as a KrF excimer laser (with a wavelength of 248 nm), an ArF excimer laser (with a wavelength of 193 nm), or an F2 excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates Ebs or EUV rays. During exposure, the exposure may be usually performed through a mask corresponding to a desired pattern, but when exposure light is an EB, the exposure may be performed through direct writing without using a mask.

Regarding an integral dose of high-energy rays, for example, when EUV rays are used as the high-energy rays, the integral dose may be 2,000 mJ/cm² or less, specifically, 500 mJ/cm² or less. In addition, when Ebs are used as the high-energy rays, the integral dose may be 5,000 μC/cm² or less, specifically, 1,000 μC/cm² or less.

Although not limited to a particular theory, a main chain of the polymer of the resist composition may be decomposed (chain-scission) in the exposed portion 111 by exposure, and a portion (that is, a photo-decomposable group) of a side chain of the polymer may be deprotected to decrease a molecular weight of the polymer. Therefore, the solubility and/or dissolution rate of the polymer in a developer, in particular, an alkaline developer, may be increased.

In addition, post-exposure bake (PEB) may be performed after the exposure. A lower limit of a temperature of the PEB may be 50° C. or more, specifically, 80° C. or more. An upper limit of the temperature of the PEB may be 180° C. or less, specifically, 130° C. or less. A lower limit of a time of the PEB may be 5 seconds or more, specifically, 10 seconds or more. An upper limit of the time of the PEB may be 600 seconds or less, specifically, 300 seconds or less.

Next, as shown at FIGS. 1 and 2C, the exposed resist film 110 may be developed by using a developer. The exposed portion 111 may be washed away by the developer, and the unexposed portion 112 may remain unwashed away by the developer.

Examples of the developer may include an alkaline developer and a developer including an organic solvent (hereinafter also referred to as “organic developer”). Examples of a developing method may include a dipping method, a puddle method, a spray method, a dynamic injection method, and the like. A developing temperature may be, for example, in a range of about 5° C. to about 60° C., and a developing time may be, for example, in a range of about 5 seconds to about 300 seconds.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of a content of the alkaline compound in the alkaline developer may be 0.1 wt % or more, specifically, 0.5 wt % or more, and more specifically, 1 wt % or more. In addition, an upper limit of the content of the alkaline compound in the alkaline developer may be 20 wt % or less, specifically, 10 wt % or less, and more specifically, 5 wt % or less.

After developing, the resist pattern can be washed with ultrapure water, and then the remaining water on the substrate and pattern can be removed.

Examples of the organic solvent included in the organic developer may include the same organic solvent as those exemplified in the part of <Organic solvent> of [Resist composition].

A lower limit of a content of the organic solvent in the organic developing solvent may be 80 wt % or more, specifically, 90 wt % or more, more specifically, 95 wt % or more, or particularly, 99 wt % or more.

The organic developing solvent may also include a surfactant. In addition, a trace amount of water may be included in the organic developing solvent. Furthermore, during developing, the developing may be stopped by substituting the organic developer with a solvent that is a different type therefrom.

The resist pattern after the developing may be further cleaned. Ultrapure water, a rinse solution, or the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate 100 and the resist pattern may be removed. In addition, when ultrapure water is used, water remaining on the substrate 100 and the resist pattern may be removed.

In addition, developers may be used singly or in a combination of two or more.

In some example embodiments, a method may include manufacturing a semiconductor device, an electronic device, or any combination thereof based on processing the developed exposed resist film and/or a structure based thereon (e.g., a developed photoresist pattern, a pattern interconnection substrate, etc.).

For example, the manufacturing may include, after the resist pattern is formed as described above, obtaining a pattern interconnection substrate through etching. The etching may be performed through a known method including dry etching using a plasma gas and wet etching using an alkaline solution, a copper (II) chloride solution, an iron (II) chloride solution, or the like.

The manufacturing may include, after the resist pattern is formed, performing plating. The plating is not particularly limited, and examples thereof may include copper plating, solder plating, nickel plating, gold plating, and the like.

The manufacturing may include peeling off resist pattern remaining after the etching with an organic solvent. Example embodiments are not limited thereto, but examples of such an organic solvent may include PGMEA, PGME, EL, and the like. A peeling method is not particularly limited, but examples thereof may include an immersion method, a spray method, and the like. In addition, the pattern interconnection substrate on which the resist pattern is formed may be a multilayer interconnection substrate or may have small-diameter through-holes.

In some example embodiments, the manufacturing may include forming the pattern interconnection substrate through a method of forming a resist pattern, depositing a metal in a vacuum, and then melting the resist pattern with a solution, that is, a lift-off method.

In some example embodiments, the manufacturing may include incorporating a structure that is formed based on processing the developed photoresist pattern or a structure based thereon (e.g., the pattern interconnection substrate as described above) into a manufactured semiconductor device, a manufactured electronic device, or any combination thereof. A semiconductor device may include, for example a transistor, but example embodiments are not limited thereto. The electronic device may include, for example, one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality of the manufactured electronic device and/or any portions thereof.

The electronic device may include one or more devices, structures, or the like (e.g., one or more semiconductor devices in one or more processors, memories, processing circuitry, etc.) which may include the resist pattern and/or a structure based thereon (e.g., a pattern wiring substrate). As a result, the electronic device may have improved performance, compactness, or the like based on including one or more devices, structures, or the like that are based on (e.g., include, incorporate, or the like) the resist pattern and/or a structure based thereon (e.g., a pattern wiring substrate), which is formed using a resist composition with improved sensitivity, resolution, storage stability, and the like as described herein, such that one or more patterns of the resist pattern and/or a structure based thereon (e.g., a pattern wiring substrate) may have improved resolution, compactness (e.g., miniaturization), or the like. Accordingly, the electronic device and/or one or more devices thereof that are based on the resist pattern may have improved miniaturization due to including fine patterns while also having improved reliability due to reduced risk of having process defects due to improved uniformity of patterns thereof, reduced surface roughness thereof, reduction or prevention of acid diffusion, and/or with reduced or minimized exposure to high doses of light to complete manufacture thereof. As a further result, the yield of manufacture of defect-free electronic devices may thus be improved, and/or costs of manufacture thereof may be reduced, based on the method according to some example embodiments.

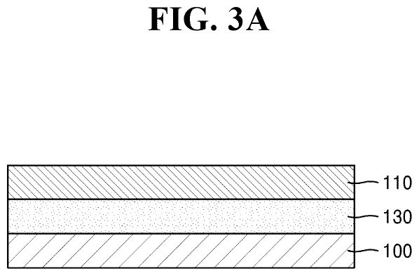

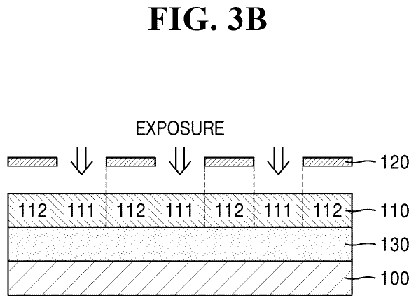

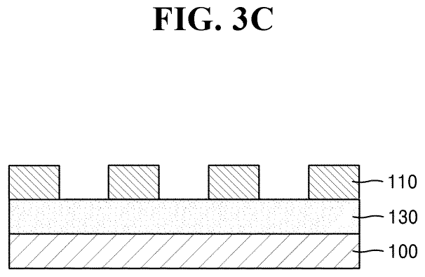

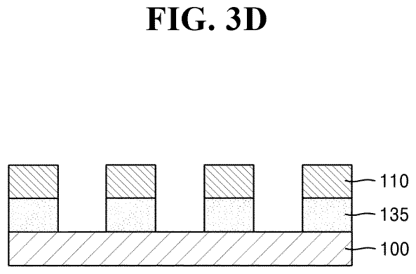

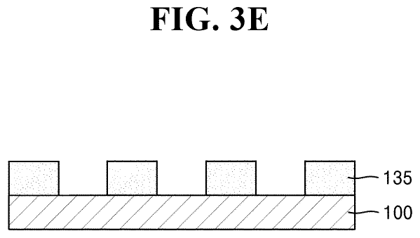

FIGS. 3A, 3B, 3C, 3D, and 3E are cross-sectional side views illustrating a method of forming a patterning structure according to some example embodiments.

As shown in FIG. 3A, before a resist film 110 is formed on a substrate 100 at S101 in FIG. 1, a material layer 130 may be formed on the substrate 100. At S101, the resist film 110 (which may include a resist composition according to any of the example embodiments and thus may include the polymer according to any of the example embodiments) may be formed on the material layer 130. The material layer 130 may include an insulating material (for example, silicon oxide or silicon nitride), a semiconductor material (for example, silicon), or a metal (for example, copper). In some example embodiments, the material layer 130 may have a multi-layer structure. A material of the material layer 130 may be different from a material of the substrate 100.

As shown in FIG. 3B, the resist film 110 may be subjected to a pre-exposure bake process and exposed to high-energy light through a mask 120, and then the resist film 110 may include an exposed portion 111 and an unexposed portion 112.

As shown in FIG. 3C, the exposed resist film 110 may be developed by using a developer (for example, a developing agent). The exposed portion 111 may be washed away by the developer, and the unexposed portion 112 may remain unwashed away by the developer.

As shown in FIG. 3D, an exposed portion of the material layer 130 may be etched by using the resist film 110 as a mask to form a material pattern 135 on the substrate 100.

As shown in FIG. 3E, the resist film 110 may be removed.

In some example embodiments, a semiconductor device, an electronic device, or any combination thereof may be manufactured using the material pattern 135 on the substrate 100.

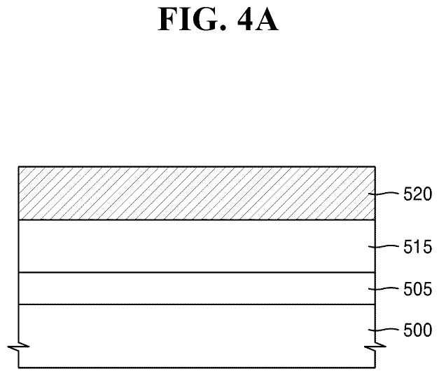

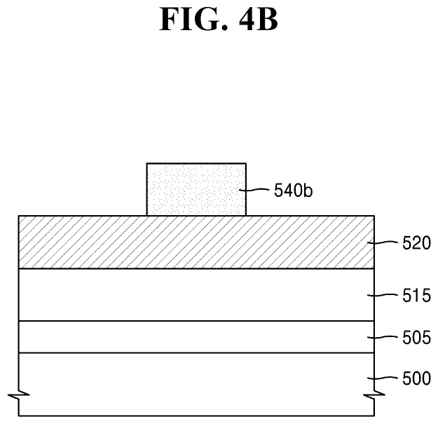

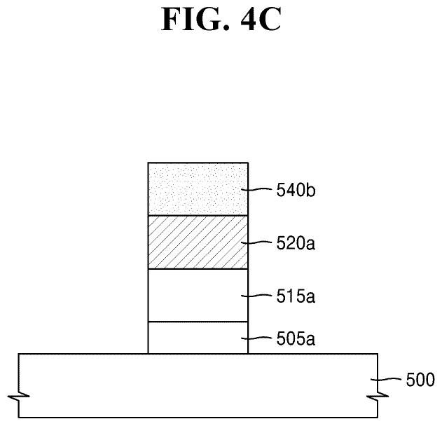

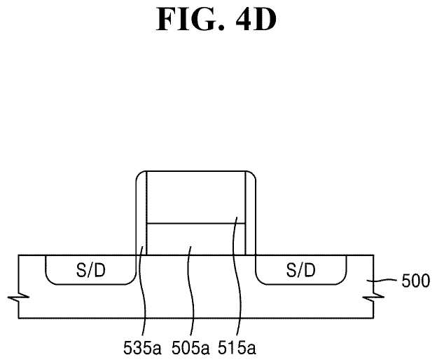

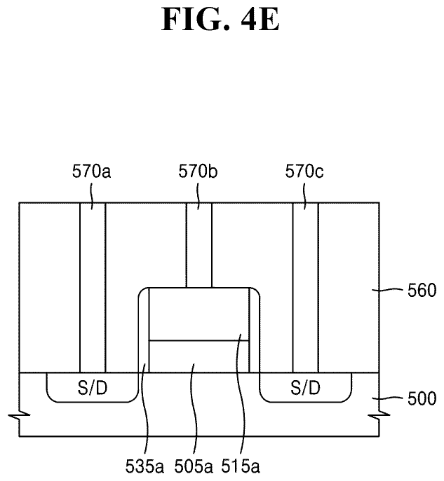

FIGS. 4A, 4B, 4C, 4D, and 4E are side cross-sectional views illustrating a method of forming a semiconductor device according to some example embodiments.

As shown in FIG. 4A, a gate dielectric 505 (for example, silicon oxide) may be formed on a substrate 500. The substrate 500 may be a semiconductor substrate such as a silicon substrate. A gate layer 515 (for example, doped polysilicon) may be formed on the gate dielectric 505. A hardmask layer 520 may be formed on the gate layer 515.

As shown in FIG. 4B, a resist pattern 540b may be formed on the hardmask layer 520. The resist pattern 540b may be formed by using a resist composition according to any of the example embodiments and thus may include the polymer according to any of the example embodiments. The resist composition may include an organic solvent.

As shown in FIG. 4C, the gate layer 515 and the gate dielectric 505 may be etched to form a hardmask pattern 520a, a gate electrode pattern 515a, and a gate dielectric pattern 505a.

As shown in FIG. 4D, a spacer layer may be formed on the gate electrode pattern 515a and the gate dielectric pattern 505a. The spacer layer may be formed by using a deposition process (for example, chemical vapor deposition (CVD)). The spacer layer may be etched to form a spacer 535a (for example, silicon nitride) on sidewalls of the gate electrode pattern 515a and the gate dielectric pattern 505a. After the spacer 535a are formed, ions may be implanted into the substrate 500 to form source/drain impurity regions S/D.

As shown in FIG. 4E, an interlayer insulating film 560 (for example, oxide) may be formed on the substrate 500 to cover the gate electrode pattern 515a, the gate dielectric pattern 505a, and the spacer 535a. Thereafter, electrical contacts 570a, 570b, and 570c connected to the gate electrode pattern 515a and the source/drain impurity regions S/D may be formed in the interlayer insulating film 560. The electrical contacts 570a, 570b, and 570c may be formed of a conductive material (for example, metal). Although not shown, a barrier layer may be formed between a sidewall of the interlayer insulating film 560 and the electrical contacts 570a, 570b, and 570c.

FIGS. 4A to 4E illustrate an example in which a transistor is formed, but the inventive concepts are not limited thereto. In some example embodiments, an electronic device may be manufactured using (e.g., incorporating via assembly) the formed semiconductor device (e.g., the transistor formed at FIGS. 4A to 4E).

The resist composition according to some example embodiments may be used in a patterning process of forming other types of semiconductor apparatuses.

The inventive concepts will be described in more detail using the following Examples and Comparative Examples, but the technical scope of the inventive concepts is not limited only to the following Examples.

### EXAMPLES

### Example 1: Synthesis of Polymer P-1

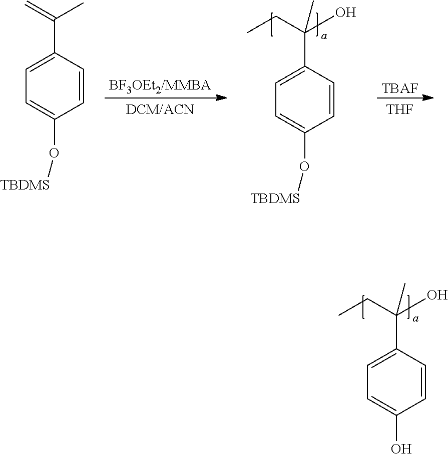

1.07 g (4.3 mmol) of 1-tertbutyldimethylsilyloxybenzene 4-methylethene (monomer A-1), 1.66 g of dichloromethane (DCM), and 2.82 g of acetonitrile (ACN) were added to a reactor. Next, while the reactor was purged with nitrogen, the reactor was cooled by using an ice bath. After 0.1 g of an initiator solution prepared by diluting 0.1 g of 4-methoxy-alpha-methylbenzyl alcohol in 0.8 g of DCM and adding 0.1 g of borontrifluoride etherate thereto was taken and added to a reactor. After a reaction was performed at a temperature 0° C. for 1 hour, 0.5 g of methanol was added and stirred again for 30 minutes, and then the reaction was terminated. A solid obtained through precipitation using methanol was vacuum-dried at a temperature of 40° C. for 8 hours. After the solid was added again to the reactor, 1 mol of tetrabutylammonium fluoride (TBAF) and 5 g of THE were added thereto and allowed to react for 24 hours. The reaction product was precipitated by using water, neutralized by using acetic acid, and then filtered to obtain a solid. The obtained solid was vacuum-dried at a temperature of 40° C. for 8 hours to obtain 0.3 g of polymer P-1 (yield: 51%, Mw: 9,632 g/mol, and PDI: 2.7).

### Example 2: Synthesis of Polymer P-2

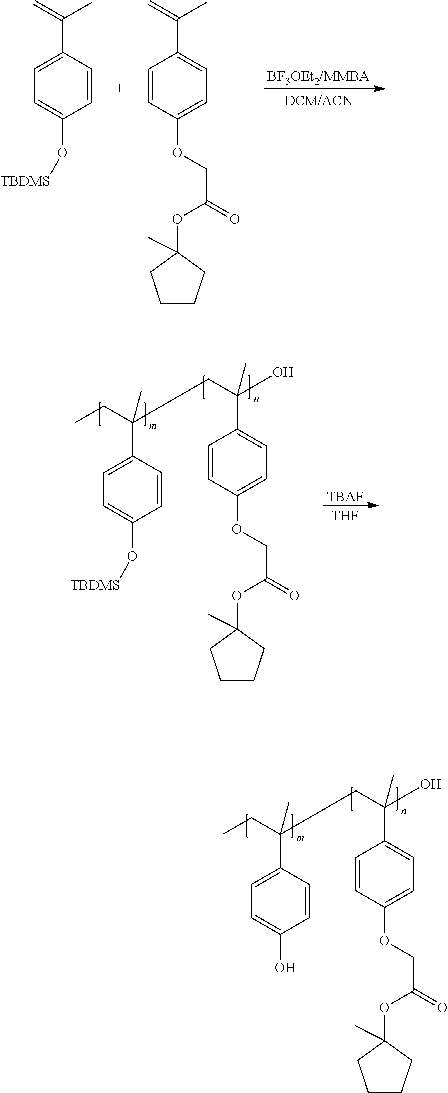

1.99 g (14 mmol) of 1-tertbutyldimethylsilyloxybenzene 4-methylethene (monomer A-1), 0.946 g (3.4 mmol) of 1-methylcyclopentyl 2-(4-methylethenylphenoxy)acetate (monomer A-2), 6 g of DCM, and 6 g of ACN were added to a reactor and maintained at a temperature of −10° C. Here, 0.026 g of borontrifluoride etherate and 0.0028 g of 4-methoxy-alpha-methylbenzyl alcohol as initiators were diluted in 0.5 ml of DCM and slowly injected. After the solution was stirred for 1 hour, 0.5 ml of methanol was injected to terminate the reaction. The reaction products were precipitated by using methanol, filtered, and then dried in a vacuum oven. 20 g of tetramethylammoniumfluoride 1M in a THE solution was added to the dried solids and allowed to react overnight. After it was confirmed that all solids were dissolved, the reaction was terminated. Water was added to the reaction products to precipitate the reaction products, acetic acid was added, and then the solution was extracted by using ethyl acetate (EA). The extracted solution was dried with sodium sulfate, and then precipitation was performed by using hexane to obtain 1.6 g of polymer P-2 (yield: 60%, Mw: 10,148 g/mol, and PDI: 2.2).

### Synthesis Examples 3 to 5: Synthesis of Polymers P-3 to P-5

Polymers P-3 to P-5 were synthesized in the same manner as in Synthesis Example 2, except that a content of a monomer was changed as shown in Table 1 below.

### Synthesis Example 6: Synthesis of Polymer P-6

0.4 g of polymer P-1 synthesized in Synthesis Example 1 was added to 1.88 g of a THF/pyridine mixed solvent (weight ratio of 3:1) 0.132 g of ditertbutyldicarbonate was added thereto and stirred overnight. After a reaction was completed, water was added and stirred for 4 hours to obtain a precipitate. The obtained precipitate was added to a water/ammonium chloride/MeOH mixed solution and precipitated to remove residual pyridine. The precipitate was dried to obtain 0.2 g of polymer P-6 (yield: 51%, Mw: 6,320 g/mol, and PDI: 1.4).

### Synthesis Example 7: Synthesis of Polymer P-7

0.2 g of polymer P-7 (yield: 51%, Mw: 5,820 g/mol, and PDI: 1.5) was obtained in the same manner as in Synthesis Example 6, except that only a content of ditertbutyldicarbonate was adjusted.

### Synthesis Example 8: Synthesis of Polymer P-X

0.87 g (3.49 mmol) of 1-ethylcyclopentyl 3,5-dihydroxybenzoate (monomer B-1) and 1.21 g (3.49 mmol) of 1,4-phenylenebis(propane-2,2-diyl)bis(2-chloroacetate) (monomer B-2) were added to DMF. 0.74 g of sodium carbonate and 0.17 g of potassium iodide were added thereto and allowed to react at a temperature of 60° C. for 24 hours. When the reaction was completed, the reaction product was precipitated by adding water, and a solid obtained through filtering was dried at a temperature of 40° C. in a vacuum oven to obtain 2.1 g of polymer P-X (yield: 70%, Mw: 7,812 g/mol, and PDI: 1.92).

### Synthesis Example 9: Synthesis of Polymer P-Y

1.7 g of polymer P-Y (yield: 56%, Mw: 3,791 g/mol, and PDI: 1.67) was obtained in the same manner as in Synthesis Example 8, except that potassium iodide was not used.

### Synthesis Example 10: Synthesis of Polymer P-Z

1.07 g (6.54 mmol) of 4-acetoxystyrene (monomer B-3) and 1.62 g (6.54 mmol) of 2-Ethyl-2-methacryloyloxyadamantane (monomer B-4) were added to 12 g of 1,4-dioxane. 0.30 g (1.3 mmol) of dimethyl 2,2′-azobis(2-methylpropionate) as an initiator was added thereto. A reactor was placed on a hotplate and heated to a temperature of 80° C. and stirred. After 4 hours, hexane was added, precipitation was performed, and filtering was performed to obtain a solid. The obtained solid was dried at a temperature of 40° C. in a vacuum oven. After the dried solid was added to 24 g of methanol, 2.82 g of a 25 wt % methanol solution of sodium methoxide was added and stirred for 4 hours or more. When a reaction was completed, the reaction product was precipitated by using water and neutralized by adding a small amount of acetic acid. The neutralized product was extracted with EA and dried by using sodium sulfate, and EA was concentrated by using an evaporator to precipitate a solid by using hexane. The precipitated solid was vacuum-dried to obtain 1.4 g of polymer P—Z (yield: 46%, Mw: 4,650 g/mol, and PDI: 1.4).

A weight average molecular weight and PDI of the polymers obtained in Synthesis Examples 1 to 10 are listed in Table 1 below.

TABLE 1

| | | | Weight | |
|---|---|---|---|---|
| | | | average | |
| | | | molecular | |
| Polymer | Monomer | Molar ratio | weight (Mw) | PDI |
| P-1 | A-1 | 100 | 9,600 | 2.7 |
| P-2 | A-1/A-2 | 70/30 | 10,000 | 3.24 |
| P-3 | A-1/A-2 | 38/62 | 4,600 | 1.2 |
| P-4 | A-1/A-2 | 38/62 | 5,100 | 1.2 |
| P-5 | A-1/A-2 | 67/33 | 5,518 | 1.7 |
| P-6 | A-1/A-3 | 74/26 | 9,045 | 1.5 |
| P-7 | A-1/A-3 | 18/82 | 6,215 | 1.4 |
| P-X | B-1/B-2 | 50/50 | 7,182 | 1.9 |
| P-Y | B-3/B-4 | 50/50 | 3,791 | 1.6 |
| P-Z | B-3/B-4 | 40/60 | 4,352 | 1.8 |

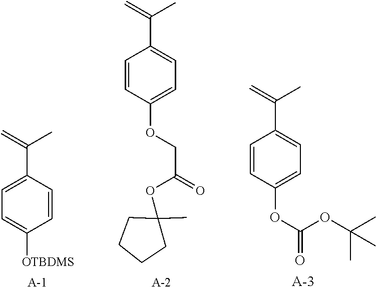

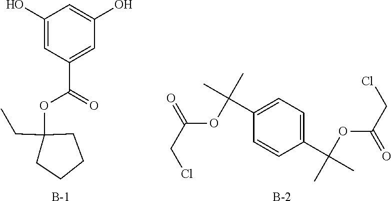

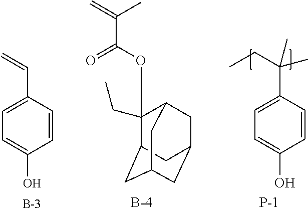

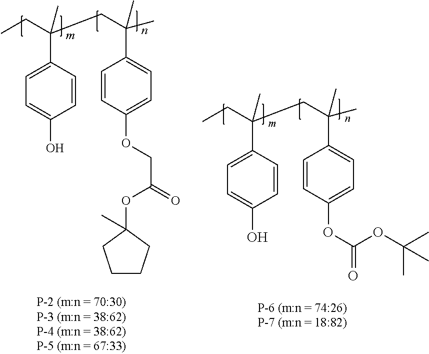

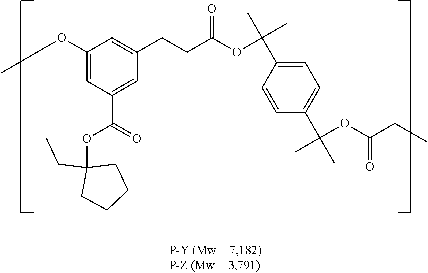

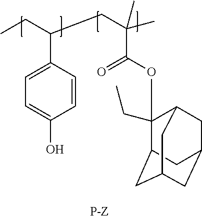

### Evaluation Example 1: Thin Film Phenomenon Evaluation

### (1) Terminology

E₀ denotes an exposure amount at a point at which a thin film is completely developed (the thin film no longer becomes thinner), and E₁ denotes an exposure amount at a point at which the thin film starts to be developed. y is a value calculated from a contrast curve through Equation 1 below and corresponds to a magnitude of photosensitivity and sensitivity of the thin film.

$$γ = {[ ln ( \frac{{E}_{0}}{{E}_{1}} ) ]}^{- 1} \qquad Equation 1$$

### (2) Thin Film Phenomenon Evaluation

The polymer was dissolved in a content of 1 0.5 wt % in a casting solvent of PGME/PGMEA=7/3 w/w, and the following 23 mmol PAG as an acid generator and the following 20 mmol PDQ as a quencher were further added thereto with respect to 100 parts by weight of the polymer and then filtered through a 0.2 μm membrane filter. The casting solution was applied onto a hexamethyldisilane (HMDS)-treated silicon wafer at a speed of 1500 rpm through spin coating and then dried (PAB) at a temperature of 110° C. for 1 minute to manufacture a film. Next, the film was exposed to EUV with a wavelength of 13.5 nm at a dose of 0 mJ/cm² to 200 mJ/cm² and then optionally dried (PEB) at a temperature of 90° C. for 1 minute to manufacture a film (PEB was not performed in Example 5, Comparative Example 1, and Comparative Example 3). The obtained film was washed with a 2.38 wt % TMAH aqueous solution at a temperature of 25° C. for 10 seconds, washed with water, and then naturally dried to then measure a thickness of the remaining film by using a film thickness measurement instrument (Filmetrics®, F-20). Measurement results are shown in Table 2.

TABLE 2

| | | | E₁ | E₀ | | Quality |
|---|---|---|---|---|---|---|
| Example | Poly- | PEB | (mJ/ | (mJ/ | | after |
| No. | mer | (° C.) | cm²) | cm²) | γ | developing |
| Example 1 | P-1 | 90 | 7.82 | 14.71 | 1.71 | Good |
| Example 2 | P-2 | 90 | 8.45 | 15.33 | 1.71 | Good |
| Example 3 | P-3 | 90 | 12.54 | 16.16 | 3.35 | Good |
| Example 4 | P-4 | 90 | 16.29 | 22.1 | 2.83 | Good |
| Example 5 | P-5 | 90 | 8.41 | 14.59 | 2.15 | Good |
| Example 6 | P-6 | 90 | 12.54 | 22.51 | 1.65 | Good |
| Example 7 | P-7 | 90 | 15.25 | 24.3 | 2.14 | Good |
| Comparative | P-X | 90 | 14.47 | 31.2 | 1.3 | Bad* |
| Example 1 | | | | | | |
| Comparative | P-Y | 90 | 14.71 | 43.1 | 0.93 | Bad* |
| Example 2 | | | | | | |
| Comparative | P-Z | 90 | 21.3 | 55.07 | 1.05 | Good |
| Example 3 | | | | | | |

*A film having a thickness of 10 nm to 20 nm remained after developing.

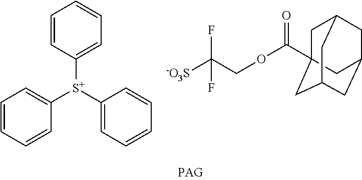

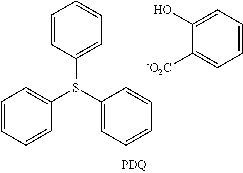

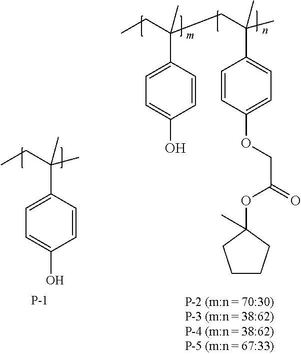

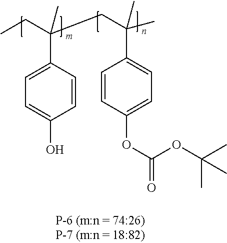

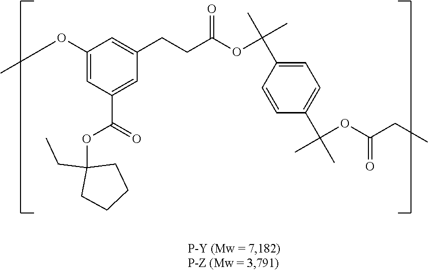

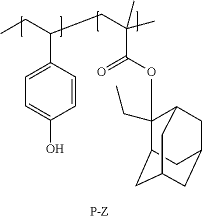

Referring to Table 2, it could be seen that the solubility of all of polymers P-1 to P-7 in a developer was changed after exposure to EUV.

Referring to Table 2, it can be confirmed that resist compositions adopting polymers P-1 to P-7 according to some example embodiments exhibit larger y as compared with resist compositions adopting polymers P—X, P—Y, and P—Z. Thus, it can be confirmed that the resist compositions including polymers P-1 to P-7 have improved photosensitivity and sensitivity than the resist compositions including polymers P—X, P—Y, and P—Z.

In particular, it could be confirmed that polymers P—X and P—Y using the conventional chain decomposition method were not suitable for use in fine patterns because residual films remained after developing.

Some example embodiments may provide a polymer of which physical properties are changed even at a low dose, a resist composition including the same, and a pattern formation method using the resist composition.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the FIGS., it will be understood by those of ordinary skill in the art that various changes in form and details may be made therein without departing from the spirit and scope as defined by the following claims.

What is claimed:

1. A polymer, comprising:
a polymer chain including a first repeating unit represented by Formula 1; and
a terminus including at least one of an amino group, a hydroxy group, a C₁-C₁₀ alkoxy group, or a C₁-C₁₀ ester group: 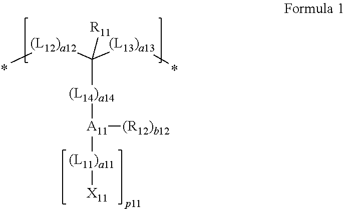
wherein, in Formula 1,
L₁₁ to L₁₄ are each independently a single bond, O, S, C(═O), C(═O)O, OC(═O), C(═O)NH, NHC(═O), S(═O), S(═O)₂, S(═O)₂O, OS(═O)₂, or a linear, branched, or cyclic C₁-C₃₀ divalent hydrocarbon group optionally containing a heteroatom,
a11 to a14 are each independently an integer from 1 to 4,
A₁₁ is a C₆-C₃₀ aryl group or a C₁-C₃₀ heteroaryl group,
R₁₁ is a halogen, a cyano group, or a linear, branched, or cyclic C₁-C₃₀ monovalent hydrocarbon group optionally containing a heteroatom,
R₁₂ is hydrogen, deuterium, a halogen, a cyano group, a hydroxy group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom,
X₁₁ is a hydroxy group, a carboxylate group, an ester moiety, a sulfonate moiety, a carbonate moiety, a lactone moiety, a sultone moiety, a carboxylic anhydride moiety, a linear, branched, or cyclic C₁-C₃₀ monovalent hydrocarbon group optionally containing a heteroatom, or an acid labile group,
b12 is an integer from 1 to 10,
p11 is an integer from 1 to 3, and
* is a binding site with an adjacent atom.

2. The polymer of claim 1, wherein, in Formula 1, L₁₁ to L₁₄ are each independently a single bond, O, S, C(═O), C(═O)O, OC(═O), C(═O)NH, NHC(═O), S(═O), S(═O)₂:S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

3. The polymer of claim 1, wherein, in Formula 1, A₁₁ is one of a phenyl group, a biphenyl group, a terphenyl group, a naphthyl group, a phenanthrenyl group, an anthracenyl group, a triphenylenyl group, a pyrenyl group, a chrysenyl group, a pyrrolyl group, a thiophenyl group, a furanyl group, an imidazolyl group, a pyrazolyl group, a thiazolyl group, an oxazolyl group, a pyridinyl group, a pyrazinyl group, a pyrimidinyl group, a pyridazinyl group, an indolyl group, a quinolinyl group, an isoquinolinyl group, a benzoquinolinyl group, a quinoxalinyl group, a quinazolinyl group, or a cynolinyl group.

4. The polymer of claim 1, wherein, in Formula 1, A₁₁ is one of a phenyl group, a biphenyl group, a terphenyl group, or a naphthyl group.

5. The polymer of claim 1, wherein, in Formula 1,
R₁₁ is one of a halogen; a cyano group; a C₁-C₂₀ alkyl group; a C₃-C₂₀ cycloalkyl group; or a C₆-C₂₀ aryl group, and
each of the C₁-C₂₀ alkyl group, the C₃-C₂₀ cycloalkyl group, and the C₆-C₂₀ aryl group is independently unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

6. The polymer of claim 1, wherein, in Formula 1,
R₁₂ is one of hydrogen; deuterium; a halogen; a cyano group; a hydroxy group; an amino group; a carboxylate group; a thiol group; a C₁-C₂₀ alkyl group; a C₃-C₂₀ cycloalkyl group; or a C₆-C₂₀ aryl group, and
each of the C₁-C₂₀ alkyl group, the C₃-C₂₀ cycloalkyl group, and the C₆-C₂₀ aryl group is independently unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

7. The polymer of claim 1, wherein, in Formula 1,
X₁₁ is one of an acid labile group; a hydroxy group; a carboxylate group; an ester moiety; a sulfonate moiety; a carbonate moiety; a lactone moiety; a sultone moiety; a carboxylic anhydride moiety; a C₁-C₂₀ alkoxy group; a C₃-C₂₀ cycloalkoxy group; or a C₆-C₂₀ aryloxy group, and
each of the C₁-C₂₀ alkoxy group, the C₃-C₂₀ cycloalkoxy group, and the C₆-C₂₀ aryloxy group is independently unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

8. The polymer of claim 1, in Formula 1, wherein the acid labile group is represented by any one of Formulas 6-1 to 6-11: 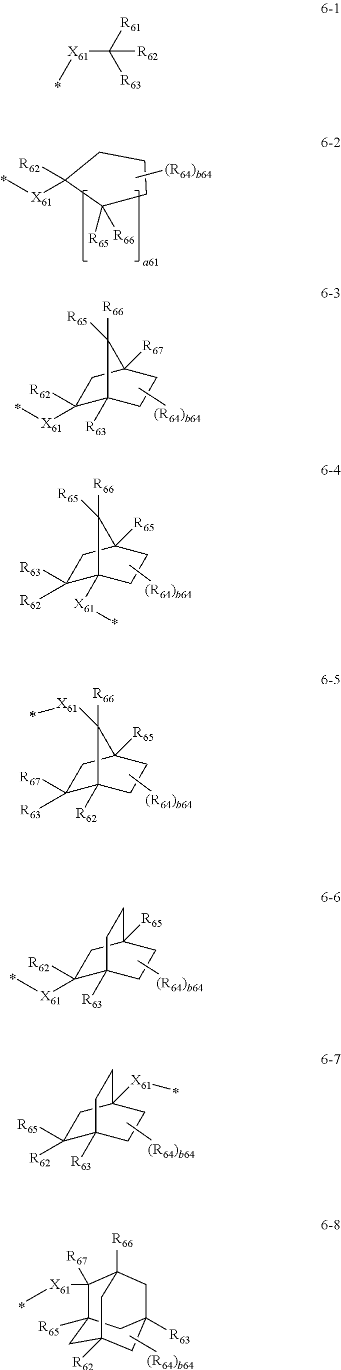 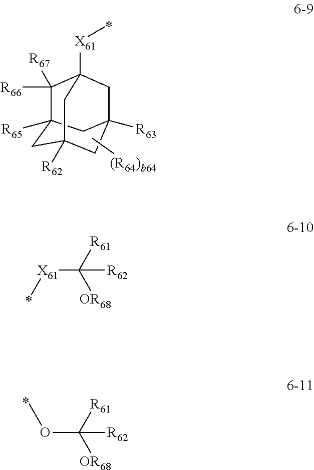
wherein, in Formulas 6-1 to 6-11,
X₆₁ is an ester moiety, a sulfonate moiety, a carbonate moiety, or a carbamate moiety,
a61 is an integer from 0 to 6,
R₆₁ and R₆₈ are each independently a linear, branched, or cyclic C₁-C₂₀ monovalent hydrocarbon group optionally containing a heteroatom,
R₆₂ to R₆₇ are each independently hydrogen, deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom,
two adjacent groups of R₆₁ to R₆₈ are optionally bonded to each other to form a ring,
b64 is an integer from 1 to 10, and
* is a binding site with an adjacent atom of Formula 1.

9. The polymer of claim 1, wherein the terminus is represented by any one of Formulas 10-1 to 10-4: 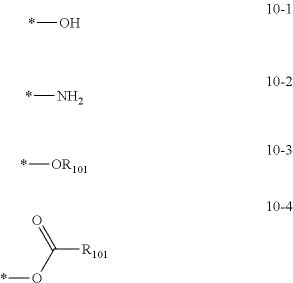
wherein, in Formulas 10-1 to 10-4,
R₁₀₁ is a methyl group, an ethyl group, an n-propyl group, an iso-propyl group, an n-butyl group, an iso-butyl group, a sec-butyl group, a tert-butyl group, an n-pentyl group, an iso-pentyl group, a 2-methylbutyl group, a sec-pentyl group, a tert-pentyl group, a neo-pentyl group, a 3-pentyl group, or a 3-methyl-2-butyl group, and
* is a binding site with the polymer chain.

10. The polymer of claim 1, wherein the terminus is *—OH.

11. The polymer of claim 1, wherein the first repeating unit is represented by Formula 1-1: 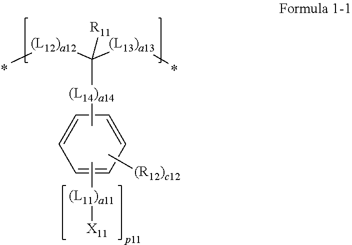
wherein, in Formula 1-1,
L₁₁ to L₁₄, a11 to a14, X₁₁, R₁₁, R₁₂, and p11 are the same as L₁₁ to L₁₄, a11 to a14, X₁₁, R₁₁, R₁₂, and p11, respectively, as defined in Formula 1,
c12 is an integer from 1 to 4, and
* is a binding site with an adjacent atom.

12. The polymer of claim 1, wherein the first repeating unit is selected from Group I:

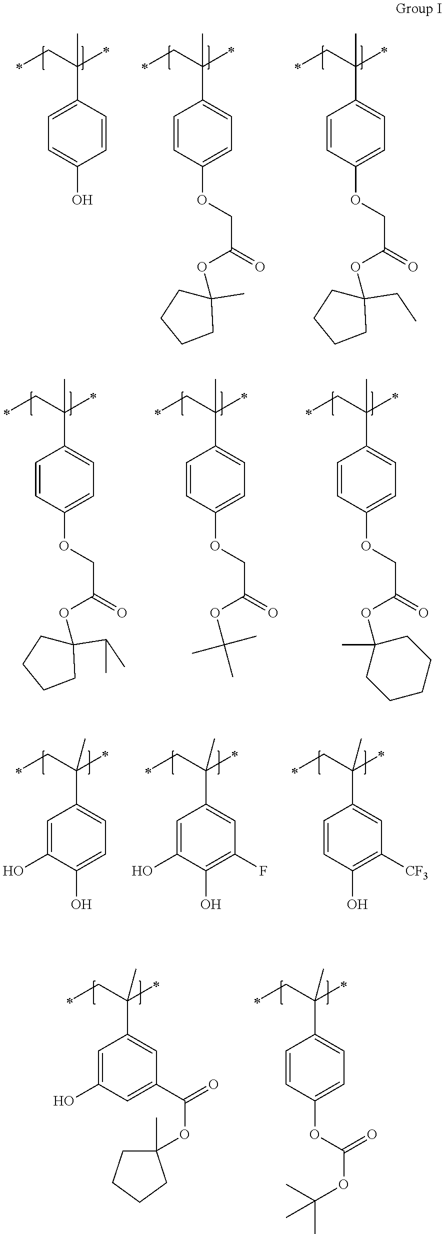

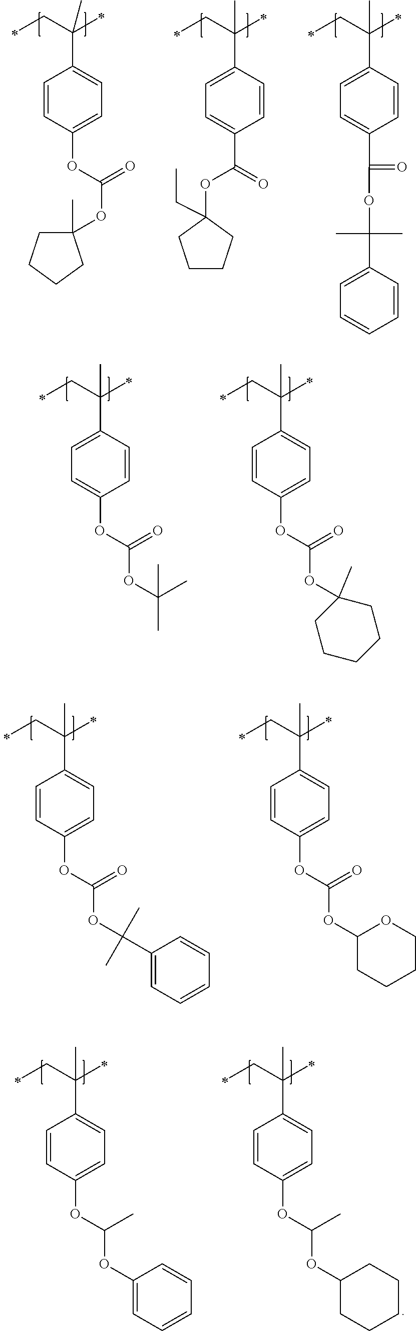

13. The polymer of claim 1, wherein the polymer chain further comprises at least one of a second repeating unit represented by Formula 2 or a third repeating unit represented by Formula 3: 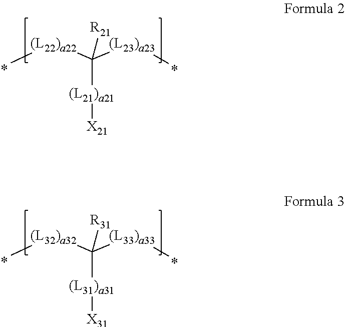
wherein, in Formula 2 and Formula 3,
L₂₁ to L₂₃ and L₃₁ to L₃₃ are each independently a single bond, O, S, C(═O), C(═O)O, OC(═O), C(═O)NH, NHC(═O), S(═O), S(═O)₂, S(═O)₂O, OS(═O)₂, or a linear, branched, or cyclic C₁-C₃₀ divalent hydrocarbon group optionally containing a heteroatom,
a21 to a23 and a31 to a33 are each independently an integer from 1 to 4,
R₂₁ and R₃₁ are each independently hydrogen, a deuterium, a halogen, a cyano group, a hydroxy group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, or a linear, branched, or cyclic C₁-C₃₀ monovalent hydrocarbon group optionally containing a heteroatom,
X₂₁ is a non-acid labile group,
X₃₁ is an acid labile group, and
* is a binding site with an adjacent atom of the polymer chain.

14. A resist composition comprising the polymer of claim 1, a photoacid generator, and an organic solvent.

15. The resist composition of claim 14, wherein the photoacid generator is represented by Formula 7: 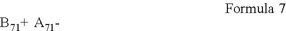
wherein, in Formula 7,
B₇₁_{⁺} is represented by Formula 7A,
A₇₁_{^{−}} is represented by any one of Formulas 7B to 7D, and
B₇₁_{⁺} and A₇₁_{^{−}} are optionally linked to each other through a carbon-carbon covalent bond: 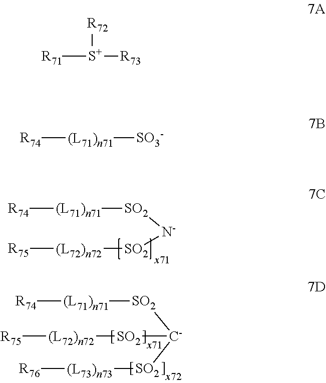
wherein, in Formulas 7A to 7D,
L₇₁ to L₇₃ are each independently a single bond or CRR′,
R and R′ are each independently hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 are each independently 1, 2, or 3,
x71 and x72 are each independently 0 or 1,
R₇₁ to R₇₃ are each independently a linear, branched, or cyclic C₁-C₃₀ monovalent hydrocarbon group optionally containing a heteroatom,
adjacent two of R₇₁ to R₇₃ are optionally bonded to each other to form a condensed ring, and
R₇₄ to R₇₆ are each independently hydrogen, a halogen, or a linear, branched, or cyclic C₁-C₃₀ monovalent hydrocarbon group optionally containing a heteroatom.

16. The resist composition of claim 14, further comprising a quencher.

17. The resist composition of claim 16, wherein the quencher is represented by Formula 8: 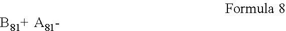
wherein, in Formula 8,
B₈₁_{⁺} is represented by any one of Formulas 8A to 8C,
A₈₁_{^{−}} is represented by any one of Formulas 8D to 8F, and
B₈₁_{⁺} and A₈₁_{^{−}} are optionally linked to each other through a carbon-carbon covalent bond, 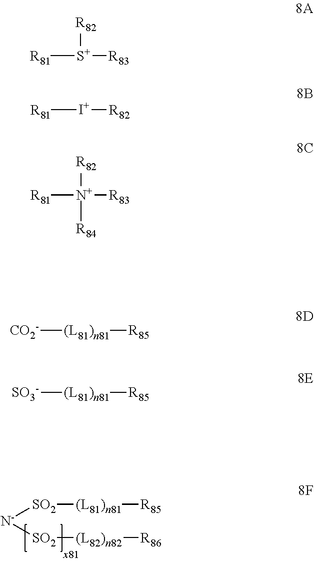
wherein, in Formulas 8A to 8F,
L₈₁ and L₈₂ are each independently a single bond or CRR′,
R and R′ are each independently hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n81 and n82 are each independently 1, 2, or 3,
x81 is 0 or 1,
R₈₁ to R₈₄ are each independently a linear, branched, or cyclic C₁-C₃₀ monovalent hydrocarbon group optionally containing a heteroatom,
adjacent two of R₈₁ to R₈₄ are optionally bonded to each other to form a condensed ring, and
R₈₅ and R₈₆ are each hydrogen, a halogen, or a linear, branched, or cyclic C₁-C₃₀ monovalent hydrocarbon group optionally containing a heteroatom.

18. A pattern formation method, comprising:
applying the resist composition of claim 14 onto a substrate to form a photoresist film;
exposing at least a portion of the photoresist film to high-energy rays; and
developing the exposed photoresist film based on using a developer.

19. The pattern formation method of claim 18, wherein the exposing is performed based on irradiating at least the portion of the photoresist film with at least one of ultraviolet rays, deep ultraviolet (DUV) rays, extreme ultraviolet (EUV) rays, X-rays, γ-rays, electron beams (EBs), or α-rays.

20. The pattern formation method of claim 18, wherein
the exposed resist film comprises an exposed portion and an unexposed portion, and
the developing comprises removing the exposed portion.
